(19) United States
(12) Patent Application Publication
(10) Pub. No.: US 2024/0423038 A1
(43) Pub. Date: Dec. 19, 2024

(54) DISPLAY DEVICE

(71) Applicant: Samsung Display Co., LTD., Yongin-si (KR)

(72) Inventors: Kyung Hoe LEE, Yongin-si (KR); Hee Rim SONG, Yongin-si (KR); So Il YOON, Yongin-si (KR); Cheol Gon LEE, Yongin-si (KR); Mu Kyung JEON, Yongin-si (KR)

(21) Appl. No.: 18/439,660

(22) Filed: Feb. 12, 2024

(30) Foreign Application Priority Data
Jun. 14, 2023 (KR) 10-2023-0076411

(51) Int. Cl. H10K 59/131

(52) U.S. Cl. CPC H10K 59/131

(57) ABSTRACT

A display device includes a substrate, a circuit layer, and an element layer. The substrate includes a display area, and a non-display area. The display area includes emission areas, a non-emission area, and light sensing areas in parts of the non-emission area. The element layer includes light emitting elements in the emission areas, and light sensing elements in the light sensing areas. The circuit layer includes light emitting pixel drivers, light sensing pixel drivers, data lines, read-out lines extending parallel to the data lines, first dummy lines extending in a first direction, and second dummy lines extending in a second direction and respectively paired with the data lines. The first dummy lines include a first read-out bypass line electrically connected to a first read-out line. The second dummy lines include a first read-out connection line electrically connected to the first read-out bypass line.

### CROSS-REFERENCE TO RELATED APPLICATION

The present application claims priority to and the benefit of Korean Patent Application No. 10-2023-0076411, filed on Jun. 14, 2023, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

With the advance of information-oriented society, more and more demand is placed on display devices for displaying images in various ways. For example, display devices are employed in various electronic devices, such as smartphones, digital cameras, laptop computers, navigation devices, and smart televisions.

The display device may be a flat panel display device, such as a liquid crystal display device, a field emission display device, and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements. Each of the light emitting elements include a light emitting layer made of an organic light emitting material. The organic light emitting display device implements an image display using a self-light emitting element, and thus, may have relatively superior performance in power consumption, response speeds, luminous efficiency, luminance, and wide viewing angles compared to those of other display devices.

The above information disclosed in this Background section is for enhancement of understanding of the background of the present disclosure, and therefore, it may contain information that does not constitute prior art.

### SUMMARY

One surface of the display device may be a display surface including a display area in which an image is displayed, and a non-display area that is at a periphery of the display area. Emission areas for emitting light with respective luminances and colors may be arranged in the display area.

The display device may additionally incorporate various input functions, as well as a function of displaying an image, in order to be suitably applied to various electronic devices.

For example, the display device may include a scanning function for detecting a curvature of an object that is in contact with a screen based on differences in the amount of light reflected from the screen.

The display device may include data transmission lines electrically connecting data lines to a display driving circuit.

Further, when incorporating the scanning function, the display device may further include light sensing elements for detecting the amount of light, and a scanning driving circuit for collecting light sensing signals generated by the light sensing elements through read-out lines.

In addition, the display device may further include read-out transmission lines for electrically connecting the read-out lines to the scanning driving circuit.

As such, in the case of a display device that further provides the scanning function as well as the display function, because the data transmission lines and the read-out transmission lines may be arranged in the non-display area, there may be a limitation in reducing the width of the non-display area.

One or more embodiments of the present disclosure are directed to a display device capable of reducing the width of the non-display area, while providing a scanning function.

According to one or more embodiments of the present disclosure, a display device includes: a substrate including: a display area including emission areas, a non-emission area as a separation region between the emission areas, and light sensing areas in parts of the non-emission area; and a non-display area around the display area; a circuit layer on the substrate; and an element layer on the circuit layer, and including: light emitting elements in the emission areas, respectively; and light sensing elements in the light sensing areas, respectively. The circuit layer includes: light emitting pixel drivers electrically connected to the light emitting elements, respectively; light sensing pixel drivers electrically connected to the light sensing elements, respectively; data lines electrically connected to the light emitting pixel drivers; read-out lines electrically connected to the light sensing pixel drivers, and extending parallel to the data lines; first dummy lines extending in a first direction crossing the data lines, and including a first read-out bypass line electrically connected to a first read-out line from among the read-out lines; and second dummy lines extending in a second direction parallel to the data lines and crossing the first direction, and paired with the data lines, respectively, the second dummy lines including a first read-out connection line electrically connected to the first read-out bypass line.

In an embodiment, the data lines, the read-out lines, and the second dummy lines may be located on at least one insulating layer covering the first dummy lines.

In an embodiment, the display device may further include a scanning driving circuit configured to collect light sensing signals from the light sensing elements through the light sensing pixel drivers and the read-out lines. The circuit layer may further include read-out transmission lines in the non-display area, and electrically connected between the read-out lines and the scanning driving circuit. From among the read-out transmission lines, a first read-out transmission line configured to transmit a signal of the first read-out line may be electrically connected to the first read-out line through the first read-out connection line and the first read-out bypass line.

In an embodiment, a bypass area on one side of the display area may include: a central bypass middle area; a first bypass side area parallel to the bypass middle area in the first direction, and in contact with the non-display area; a second bypass side area between the bypass middle area and the first bypass side area; and a third bypass side area between the first bypass side area and the second bypass side area. The data lines may include: a first data line in the first bypass side area; a second data line and a third data line in the second bypass side area; and a fourth data line in the third bypass side area. The first dummy lines may further include a first data bypass line electrically connected to the first data line, and a second data bypass line electrically connected to the fourth data line. The second dummy lines may further include: a first data connection line paired with the second data line, and electrically connected to the first data bypass line; and a second data connection line paired with the third data line, and electrically connected to the second data bypass line. The first read-out connection line may be paired with the fourth data line.

In an embodiment, the display device may further include a display driving circuit configured to transmit data signals for the light emitting pixel drivers to the data lines, and the circuit layer may further include data transmission lines in the non-display area, and electrically connected between the data lines and the display driving circuit. From among the data transmission lines: a first data transmission line configured to transmit a data signal of the first data line may be electrically connected to the first data line through the first data bypass line and the first data connection line; a second data transmission line configured to transmit a data signal of the second data line may be directly electrically connected to the second data line; a third data transmission line configured to transmit a data signal of the third data line may be directly electrically connected to the third data line; and a fourth data transmission line configured to transmit a data signal of the fourth data line may be electrically connected to the first data line through the second data bypass line and the second data connection line.

In an embodiment, the substrate may include a main region including the display area and the non-display area, and a sub-region protruding from one side of the main region in the second direction. The display driving circuit may be on the sub-region of the substrate, and the scanning driving circuit may be on a display circuit board connected to the sub-region of the substrate. The data transmission lines may be clustered in a part of the non-display area parallel to the second bypass side area, and the read-out transmission lines may be clustered in another part of the non-display area adjacent to the third bypass side area.

In an embodiment, the first read-out line may be located in the second bypass side area, the read-out lines may further include a second read-out line in the third bypass side area, and from among the read-out transmission lines, a second read-out transmission line configured to transmit a signal of the second read-out line may be directly electrically connected to the second read-out line.

In an embodiment, the first read-out bypass line may include a plurality of first read-out bypass lines, the first data bypass line may include a plurality of first data bypass lines, the second data bypass line may include a plurality of second data bypass lines, and at least one of the first read-out bypass lines may be located between the first data bypass lines in the second direction, or between the second data bypass lines in the second direction.

In an embodiment, each of the first bypass side area, the second bypass side area, and the third bypass side area may include: an adjacent region in contact with the non-display area in the second direction; and a separation region as a remaining region excluding the adjacent region. The first read-out bypass line may be located in the adjacent region of each of the first bypass side area, the second bypass side area, and the third bypass side area, and the first data bypass line and the second data bypass line may be located in the separation region of each of the first bypass side area, the second bypass side area, and the third bypass side area.

In an embodiment, the bypass area of the display area may further include a fourth bypass side area between the first bypass side area and the third bypass side area, the data lines may further include a fifth data line in the fourth bypass side area, and the read-out lines may further include a third read-out line in the first bypass side area, and a fourth read-out line in the fourth bypass side area. The first dummy lines may further include a second read-out bypass line electrically connected to the third read-out line, and the second dummy lines may further include a second read-out connection line paired with the fifth data line, and electrically connected to the second read-out bypass line. From among the read-out transmission lines: a third read-out transmission line configured to transmit a signal of the third read-out line may be electrically connected to the third read-out line through the second read-out connection line and the second read-out bypass line; and a fourth read-out transmission line configured to transmit a signal of the fourth read-out line may be directly electrically connected to the fourth read-out line.

In an embodiment, the data lines may further include a sixth data line in the second bypass side area, the first dummy lines may further include a third data bypass line electrically connected to the fifth data line, and the second dummy lines may further include a third data connection line paired with the sixth data line, and electrically connected to the third data bypass line.

In an embodiment, the fourth bypass side area may include an adjacent region in contact with the non-display area in the second direction, and a separation region as a remaining region excluding the adjacent region. The first read-out bypass line may be located in the adjacent region of each of the second bypass side area and the third bypass side area, the second read-out bypass line may be located in the adjacent region of each of the first bypass side area and the fourth bypass side area, and the first data bypass line and the second data bypass line may be located in the separation region of each of the first bypass side area, the second bypass side area, the third bypass side area, and the fourth bypass side area.

In an embodiment, the circuit layer may further include a first power supply line and a second power supply line in the non-display area, and configured to transmit a first power and a second power, respectively, for driving the light emitting elements. The first dummy lines may further include first auxiliary lines electrically connected to the second power supply line, and the second dummy lines may further include second auxiliary lines electrically connected to the first auxiliary lines and the second power supply line.

In an embodiment, each of the first bypass side area, the second bypass side area, the third bypass side area, and the fourth bypass side area may further include a buffer region between the adjacent region and the separation region, and the first auxiliary lines may be located in the buffer region of each of the first bypass side area, the second bypass side area, the third bypass side area, and the fourth bypass side area.

In an embodiment, the circuit layer may further include: a first power supply line and a second power supply line in the non-display area, and configured to transmit a first power and a second power, respectively, for driving the light emitting elements; and a first power line electrically connected between the light emitting pixel drivers and the first power supply line. One of the light emitting elements may be electrically connected between one of the light emitting pixel drivers and the second power, and one of the light sensing elements may be electrically connected between an element output node of one of the light sensing pixel drivers and the second power. The one of the light emitting pixel drivers may include: a first transistor configured to generate a driving current for driving the one of the light emitting elements; a second transistor electrically connected between one of the data lines and a first electrode of the first transistor; a third transistor electrically connected between a gate electrode of the first transistor and a second electrode of the first transistor; a fourth transistor electrically connected between a first initialization power line configured to transmit a first initialization power and the gate electrode of the first transistor; a fifth transistor electrically connected between the first power line and the first electrode of the first transistor; a sixth transistor electrically connected between the second electrode of the first transistor and the one of the light emitting elements; a seventh transistor electrically connected between a second initialization power line configured to transmit a second initialization power and the one of the light emitting elements; and an eighth transistor electrically connected between a bias power line configured to transmit a bias power and the first electrode of the first transistor. The one of the light sensing pixel drivers may include: a ninth transistor configured to be turned on according to a voltage level of the element output node; a tenth transistor electrically connected between a reset voltage line configured to transmit a reset voltage and the element output node; and an eleventh transistor electrically connected between one of the read-out lines and the ninth transistor.

According to one or more embodiments of the present disclosure, a display device includes: a substrate including: a display area including emission areas, a non-emission area as a separation region between the emission areas, and light sensing areas in parts of the non-emission area; and a non-display area around the display area; a circuit layer on the substrate; and an element layer on the circuit layer, and including: light emitting elements in the emission areas, respectively; and light sensing elements in the light sensing areas, respectively. A bypass area on one side of the display area includes: a central bypass middle area; a first bypass side area parallel to the bypass middle area in a first direction, and in contact with the non-display area; a second bypass side area between the bypass middle area and the first bypass side area; and a third bypass side area between the first bypass side area and the second bypass side area. The circuit layer includes: light emitting pixel drivers electrically connected to the light emitting elements, respectively; light sensing pixel drivers electrically connected to the light sensing elements; data lines electrically connected to the light emitting pixel drivers; read-out lines electrically connected to the light sensing pixel drivers, and extending parallel to the data lines; a first data bypass line extending in the first direction crossing the data lines, and electrically connected to a first data line in the first bypass side area from among the data lines; a first read-out bypass line extending in the first direction crossing the data lines, and electrically connected to a first read-out line from among the read-out lines; a first data connection line extending in a second direction parallel to the data lines and crossing the first direction, the first data connection line paired with a second data line in the second bypass side area from among the data lines, and electrically connected to the first data bypass line; and a first read-out connection line extending in the second direction, and electrically connected to the first read-out bypass line.

In an embodiment, the data lines may further include a third data line in the second bypass side area, and a fourth data line in the third bypass side area. The first read-out connection line may be paired with the fourth data line, and the circuit layer may further include: a second data bypass line extending in the first direction, and electrically connected to the fourth data line; and a second data connection line extending in the second direction, paired with the third data line, and electrically connected to the second data bypass line.

In an embodiment, the display device may further include: a scanning driving circuit configured to collect light sensing signals from the light sensing elements through the light sensing pixel drivers and the read-out lines; and a display driving circuit configured to transmit data signals for the light emitting pixel drivers to the data lines. The circuit layer may further include: read-out transmission lines in the non-display area, and electrically connected between the read-out lines and the scanning driving circuit; and data transmission lines in the non-display area, and electrically connected between the data lines and the display driving circuit. From among the data transmission lines: a first data transmission line configured to transmit a data signal of the first data line may be electrically connected to the first data line through the first data bypass line and the first data connection line, a second data transmission line configured to transmit a data signal of the second data line may be directly electrically connected to the second data line, a third data transmission line configured to transmit a data signal of the third data line may be directly electrically connected to the third data line, and a fourth data transmission line configured to transmit a data signal of the fourth data line may be electrically connected to the first data line through the second data bypass line and the second data connection line. From among the read-out transmission lines, a first read-out transmission line configured to transmit a signal of the first read-out line may be electrically connected to the first read-out line through the first read-out connection line and the first read-out bypass line.

In an embodiment, the read-out lines may further include a second read-out line in the third bypass side area, and from among the read-out transmission lines, a second read-out transmission line configured to transmit a signal of the second read-out line may be directly electrically connected to the second read-out line.

In an embodiment, the first read-out bypass line may include a plurality of first read-out bypass lines, the first data bypass line may include a plurality of first data bypass lines, the second data bypass line may include a plurality of second data bypass lines, and at least one of the first read-out bypass lines may be located between the first data bypass lines in the second direction, or between the second data bypass lines in the second direction.

In an embodiment, each of the first bypass side area, the second bypass side area, and the third bypass side area may include: an adjacent region in contact with the non-display area in the second direction; and a separation region as a remaining region excluding the adjacent region. The first read-out bypass line may be located in the adjacent region of each of the first bypass side area, the second bypass side area, and the third bypass side area, and the first data bypass line and the second data bypass line may be located in the separation region of each of the first bypass side area, the second bypass side area, and the third bypass side area.

In an embodiment, the bypass area of the display area may further include a fourth bypass side area between the first bypass side area and the third bypass side area, the data lines may further include a fifth data line in the fourth bypass side area, and a sixth data line in the second bypass side area, and the read-out lines may further include a third read-out line in the first bypass side area, and a fourth read-out line in the fourth bypass side area. The circuit layer may further include: a second read-out bypass line extending in the first direction, and electrically connected to the third read-out line; a second read-out connection line extending in the second direction, paired with the fifth data line, and electrically connected to the second read-out bypass line; a third data bypass line extending in the first direction, and electrically connected to the fifth data line; and a third data connection line extending in the second direction, paired with the sixth data line, and electrically connected to the third data bypass line. From among the read-out transmission lines: a third read-out transmission line configured to transmit a signal of the third read-out line may be electrically connected to the third read-out line through the second read-out connection line and the second read-out bypass line; and a fourth read-out transmission line configured to transmit a signal of the fourth read-out line may be directly electrically connected to the fourth read-out line.

In an embodiment, the fourth bypass side area may include an adjacent region in contact with the non-display area in the second direction, and a separation region as a remaining region excluding the adjacent region. The first read-out bypass line may be located in the adjacent region of each of the second bypass side area and the third bypass side area, the second read-out bypass line may be located in the adjacent region of each of the first bypass side area and the fourth bypass side area, and the first data bypass line and the second data bypass line may be located in the separation region of each of the first bypass side area, the second bypass side area, the third bypass side area, and the fourth bypass side area.

In an embodiment, the circuit layer may further include: a first power supply line and a second power supply line in the non-display area, and configured to transmit a first power and a second power, respectively, for driving the light emitting elements; and first auxiliary lines extending in the first direction, and electrically connected to the second power supply line. Each of the first bypass side area, the second bypass side area, the third bypass side area, and the fourth bypass side area may further include a buffer region between the adjacent region and the separation region, and the first auxiliary lines may be located in the buffer region of each of the first bypass side area, the second bypass side area, the third bypass side area, and the fourth bypass side area.

According to one or more embodiments of the present disclosure, a display device may include a substrate, a circuit layer disposed on the substrate, and an element layer disposed on the circuit layer. The substrate may include a display area in which emission areas are arranged, and a non-display area disposed around (e.g., adjacent to) the display area. The display area may include a non-emission area that is a separation region between the emission areas, and light sensing areas disposed in parts of the non-emission area. The element layer may include light emitting elements respectively disposed in the emission areas, and light sensing elements respectively disposed in the light sensing areas. The circuit layer may include light emitting pixel drivers respectively electrically connected to the light emitting elements, light sensing pixel drivers electrically connected to the light sensing elements, data lines electrically connected to the light emitting pixel drivers, read-out lines electrically connected to the light sensing pixel drivers and extending parallel to or substantially parallel to the data lines, first dummy lines extending in a first direction crossing the data lines, and second dummy lines extending in a second direction parallel to or substantially parallel to the data lines, and respectively paired with the data lines. The first dummy lines may include a first read-out bypass line electrically connected to a first read-out line that is one of the read-out lines, and the second dummy lines include a first read-out connection line electrically connected to the first read-out bypass line.

According to one or more embodiments of the present disclosure, the display device may further include a scanning driving circuit for collecting light sensing signals of the light sensing elements through the light sensing pixel drivers and the read-out lines. The circuit layer may further include read-out transmission lines disposed in the non-display area, and electrically connected between the read-out lines and the scanning driving circuit. From among the read-out transmission lines, a first read-out transmission line that transmits a signal of the first read-out line may be electrically connected to the first read-out line through the first read-out connection line and the first read-out bypass line.

According to one or more embodiments of the present disclosure, a bypass area on one side of the display area may include a central bypass middle area, a first bypass side area parallel to the bypass middle area in the first direction and in contact with the non-display area, a second bypass side area disposed between the bypass middle area and the first bypass side area, and a third bypass side area disposed between the first bypass side area and the second bypass side area. The data lines may include a first data line disposed in the first bypass side area, a second data line and a third data line disposed in the second bypass side area, and a fourth data line disposed in the third bypass side area. The first dummy lines may include a first data bypass line electrically connected to the first data line, and a second data bypass line electrically connected to the fourth data line. The second dummy lines may include a first data connection line paired with the second data line and electrically connected to the first data bypass line, and a second data connection line paired with the third data line and electrically connected to the second data bypass line. The first read-out connection line may be paired with the fourth data line.

According to one or more embodiments of the present disclosure, the display device may further include a display driving circuit for transmitting data signals of the light emitting pixel drivers to the data lines. The circuit layer may further include data transmission lines disposed in the non-display area, and electrically connected between the data lines and the display driving circuit. From among the data transmission lines, a first data transmission line may be electrically connected to the first data line through the first data bypass line and the first data connection line. From among the data transmission lines, a second data transmission line and a third data transmission line may be directly electrically connected to the second data line and the third data line. From among the data transmission lines, a fourth data transmission line may be electrically connected to the first data line through the second data bypass line and the second data connection line.

According to one or more embodiments of the present disclosure, a first data line of a first bypass side area from among the data lines may be electrically connected to a first data transmission line through a first data connection line of a second bypass side area and a first data bypass line. A fourth data line of a third bypass side area from among the data lines may be electrically connected to a fourth data transmission line through a second data connection line of the second bypass side area and a second data bypass line. Accordingly, the first data transmission line and the fourth data transmission line may extend to the second bypass side area that is relatively adjacent to a sub-region, rather than extending to the first bypass side area and the third bypass side area. Accordingly, the extension length of each of the first data transmission line and the fourth data transmission line may be reduced, and thus, the width of the non-display area may be reduced.

According to one or more embodiments of the present disclosure, a first read-out line of the read-out lines may be electrically connected to a first read-out transmission line through a first read-out connection line of the third bypass side area and a first read-out bypass line. Accordingly, the first read-out transmission line may extend to the first read-out connection line of the third bypass side area, rather than to the first read-out line. Therefore, because the extension length of the first read-out transmission line disposed in the non-display area may be reduced, the width of the non-display area may be further reduced.

According to one or more embodiments of the present disclosure, a display device may include the read-out lines and the read-out transmission lines electrically connecting between the light sensing elements and the scanning driving circuit in order to embed a scanning function, but may reduce the length of the first read-out transmission line by the first read-out bypass line and the first read-out connection line, thereby reducing the width of the non-display area.

According to one or more embodiments of the present disclosure, a ratio of the display area on the display surface may be increased, and thus, the display quality of the display device may be improved.

However, the aspects and features of the present disclosure are not limited to those described above, and additional aspects and features will be set forth, in part, in the description that follows, and in part, may be apparent from the description, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of an electronic device according to one or more embodiments;

FIG. 2 is an exploded perspective view of the electronic device shown in FIG. 1;

FIG. 3 is a plan view illustrating the display device of FIG. 2;

FIG. 4 is a cross-sectional view taken along the line A-A′ of FIG. 3;

FIG. 5 is an enlarged layout diagram illustrating the part B of FIG. 3;

FIG. 6 is a diagram illustrating a scanning function by the light sensing areas shown in FIG. 5;

FIG. 7 is a block diagram of the circuit layer of FIG. 4;

FIG. 8 is an equivalent circuit diagram of the light emitting pixel driver and the light sensing pixel driver shown in FIG. 7;

FIG. 9 is a cross-sectional view illustrating the first transistor, the second transistor, the fourth transistor, the sixth transistor, and the light emitting element of FIG. 8;

FIG. 10 is a plan view illustrating the substrate of FIG. 2 according to one or more embodiments;

FIG. 11 is an enlarged layout diagram illustrating the part C of FIG. 10 according to an embodiment;

FIG. 12 is a cross-sectional view taken along the line D-D′ of FIG. 11; and

FIGS. 13-15 are enlarged layout diagrams illustrating the part C of FIG. 10 according to one or more embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. For example, “about” may mean within one or more standard deviations, or within +30%, 20%, 10%, 5% of the stated value. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

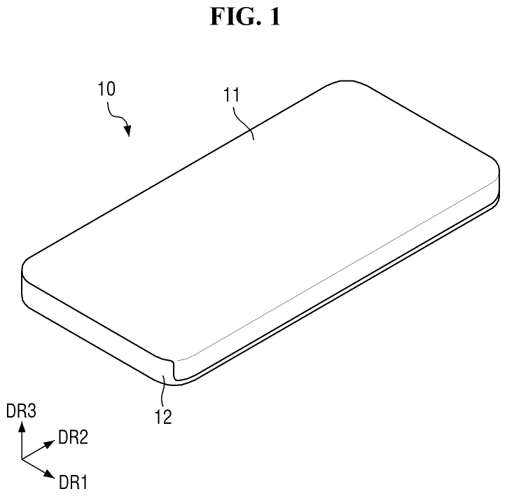

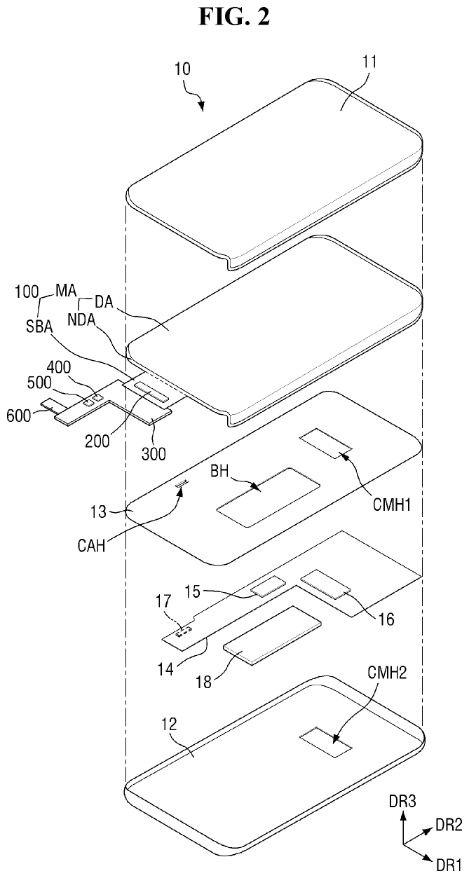

FIG. 1 is a perspective view of an electronic device according to one or more embodiments. FIG. 2 is an exploded perspective view of the electronic device shown in FIG. 1.

Referring to FIG. 1, an electronic device 10 according to an embodiment is a device having a function for displaying an image in a display area. The electronic device 10 may be a portable device. For example, the electronic device 10 may be a portable electronic device, such as a mobile phone, a smartphone, a tablet personal computer (PC), a smart watch, a watch phone, a mobile communication terminal, an electronic notebook, an electronic book, a portable multimedia player (PMP), a navigation device, and an ultra-mobile PC (UMPC).

However, the present disclosure is not limited thereto, and the electronic device 10 may be a large-sized device such as a television, a laptop computer, a monitor, a billboard, and/or an Internet-of-Things (IOT) device.

The electronic device 10 according to an embodiment may include a cover window 11 and a lower cover 12. The cover window 11 and the lower cover 12 may be provided as a housing to protect a display device 100 (e.g., see FIG. 2).

Referring to FIG. 2, the electronic device 10 may further include the display device 100, a bracket 13, and a main circuit board 14, which are accommodated between the cover window 11 and the lower cover 12.

The display device 100 may include a main region MA, and a sub-region SBA protruding from one side of the main region MA. The main region MA may include a display area DA where an image is displayed, and a non-display area NDA around (e.g., adjacent to) the display area DA.

The display device 100 may further include a display driving circuit 200 disposed in the sub-region SBA, a display circuit board 300 connected to (e.g., bonded to or attached to) one side of the sub-region SBA, a touch driving circuit 400 and a scanning driving circuit 500 on (e.g., mounted on) the display circuit board 300, and a cable 600 extending from one side of the display circuit board 300.

As used in the present specification, a first direction DR1 may be a direction parallel to or substantially parallel to a short side of the electronic device 10 in a plan view, or in other words, a horizontal direction of the electronic device 10. A second direction DR2 may be a direction parallel to or substantially parallel to a long side of the electronic device 10 in a plan view, or in other words, a vertical direction of the electronic device 10. The third direction DR3 may be a thickness direction of the electronic device 10.

The electronic device 10 may have a shape similar to or the same as a rectangular shape in a plan view. For example, in a plan view, the electronic device 10 may have a rectangular shape having the short side extending in the first direction DR1, and the long side extending in the second direction DR2. A corner where the short side extending in the first direction DR1 and the long side extending in the second direction DR2 meet each other may be right-angled or rounded with a suitable curvature (e.g., a predetermined curvature). The planar shape of the electronic device 10 is not limited to the rectangular shape, and may be formed in another polygonal shape, a circular shape, or an elliptical shape.

The cover window 11 may be disposed on the display device 100 to cover the top surface of the display device 100. The cover window 11 may serve to protect the top surface of the display device 100.

The cover window 11 may include a light transmitting portion that is transparent, and a light blocking portion that is opaque.

The light transmitting portion may overlap with the display area DA of the display device 100 in the third direction DR3, and the light blocking portion may overlap with the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion.

The light transmitting portion of the cover window 11 may be disposed on most of each of the top, left, and right surface portions of the cover window 11.

The light blocking portion of the cover window 11 may be disposed at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be disposed below the cover window 11.

In other words, the cover window 11 may be disposed on or above the display device 100.

The display device 100 may include the main region MA serving as the display surface, and the sub-region SBA protruding from one side of the main region MA.

The main region MA may include the display area DA for displaying an image, and the non-display area NDA that is a peripheral area of the display area DA.

The display area DA may be disposed in most of the main region MA. The display area DA may be disposed at the center of the main region MA.

The non-display area NDA may be disposed outside the display area DA. The non-display area NDA may be an edge area of the main region MA.

The sub-region SBA may protrude from one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but the present disclosure is not limited thereto.

Because a part of the sub-region SBA may be transformed to be bent, another part of the sub-region SBA may overlap with the main region MA in the third direction DR3.

The display driving circuit 200 may be arranged in the sub-region SBA.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

Each of the top, left, and right surface portions of the display device 100 may include the display area DA and the non-display area NDA.

The display area DA may be disposed on most of each of the top, left, and right surface portions of the display device 100.

The non-display area NDA may be disposed at the upper edge and the lower edge of the top surface portion of the display device 100, the upper edge, the left edge, and the lower edge of the left surface portion of the display device 100, and the upper edge, the right edge, and the lower edge of the right surface portion of the display device 100.

The display driving circuit 200 may be mounted on the sub-region SBA of the display device 100, and the display circuit board 300 may be attached thereto.

One end of the display circuit board 300 may be attached onto pads disposed on the lower edge of the sub-region SBA of the display device 100 by using an anisotropic conductive film.

The display circuit board 300 may be a flexible printed circuit board (FPCB) that is bendable, a rigid printed circuit board (PCB) that maintains a flat or substantially flat shape, or a composite printed circuit board having both of the rigid printed circuit board and the flexible printed circuit board.

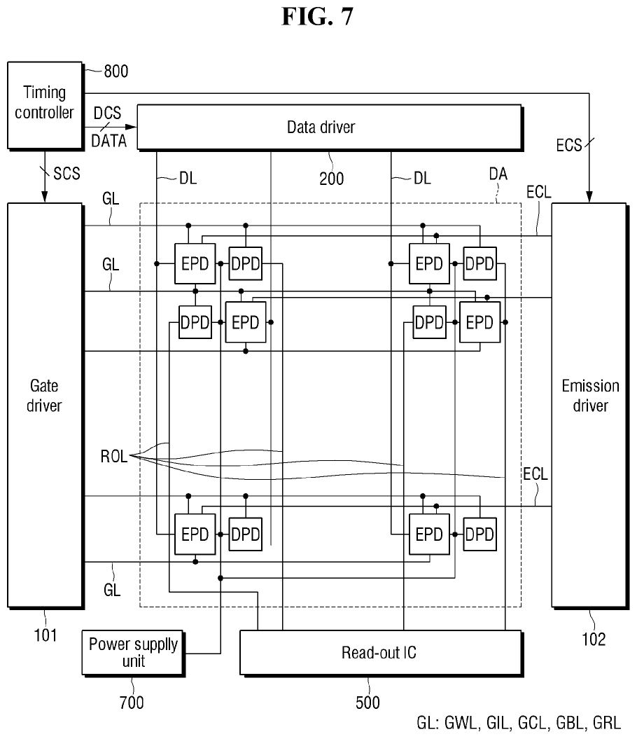

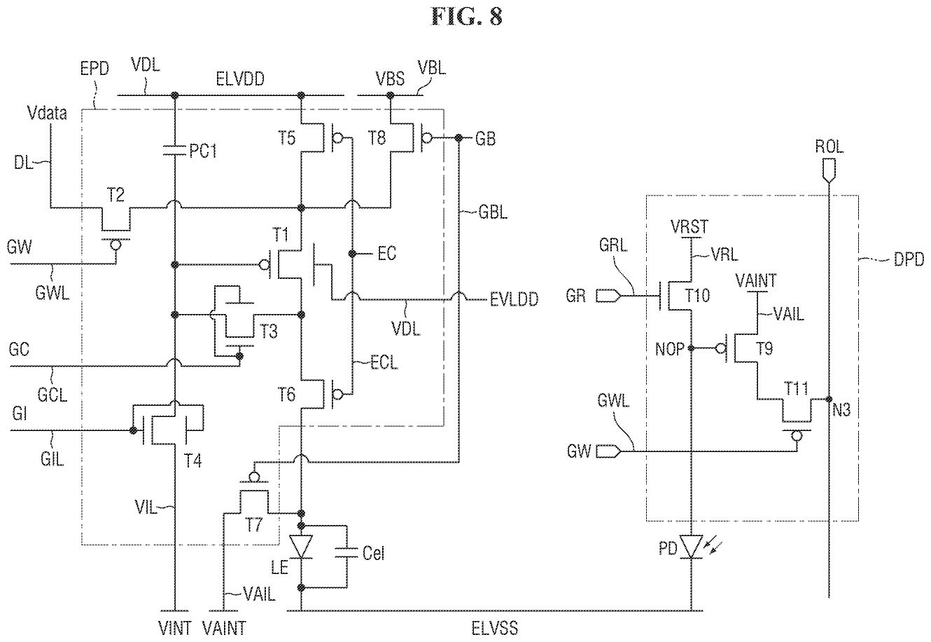

Based on control signals and power voltages supplied from the display circuit board 300, the display driving circuit 200 may transmit data signals Vdata (e.g., see FIG. 8) of light emitting pixel drivers EPD (e.g., see FIG. 7) of the display area DA to data lines DL.

The display driving circuit 200 may be provided as an integrated circuit (IC), and may be mounted on the sub-region SBA of the display device 100 by a chip on glass (COG) method, a chip on plastic (COP) method, or an ultrasonic method. However, the present disclosure is not limited thereto. For example, the display driving circuit 200 may be mounted on the display circuit board 300.

According to an embodiment, the touch driving circuit 400 and the scanning driving circuit 500 may be further mounted in the sub-region SBA of the display device 100.

In another embodiment, as shown in FIG. 2, the touch driving circuit 400 and the scanning driving circuit 500 may be mounted on the display circuit board 300.

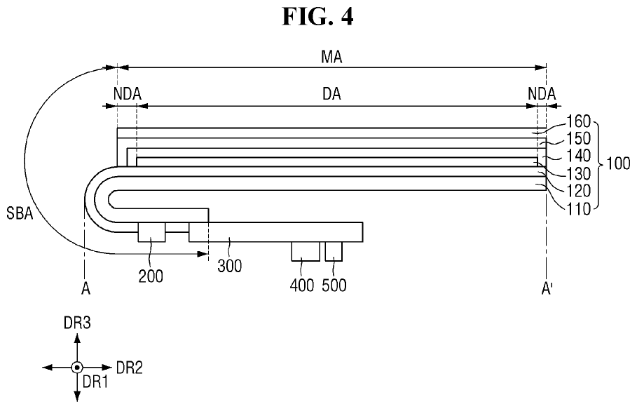

The touch driving circuit 400 may be electrically connected to a touch sensor layer 150 (e.g., see FIG. 4) of the display device 100.

The scanning driving circuit 500 may be electrically connected to light sensing elements PD (e.g., see FIG. 8) through light sensing pixel drivers DPD (e.g., see FIG. 7) and read-out lines ROL of the display area DA.

The bracket 13 may be disposed under the display device 100.

The bracket 13 may include a plastic, a metal, or both a plastic and a metal. The bracket 13 may include a first camera hole CMH1 into which a camera device 16 may be inserted, a battery hole BH into which a battery 18 may be disposed, and a cable hole CAH through which the cable 600 connected to the display circuit board 300 may be passed.

The main circuit board 14 and the battery 18 may be disposed under the bracket 13. The main circuit board 14 may be a printed circuit board or a flexible printed circuit board.

The main circuit board 14 may include a main processor 15, a camera 16, and a main connector 17. The main processor 15 may be formed as an integrated circuit.

The camera 16 may be disposed on both the top and bottom surfaces of the main circuit board 14. The main processor 15 may be disposed on the top surface of the main circuit board 14, and the main connector 17 may be disposed on the bottom surface of the main circuit board 14.

The main processor 15 may control all overall functions of the electronic device 10.

For example, the main processor 15 may output digital video data to the

display driving circuit 200 through the display circuit board 300, such that the display device 100 displays an image. In addition, the main processor 15 may receive touch data including a user's touch coordinates from the touch driving circuit 400, determine whether or not the user has touched or approached the display device 100 or the electronic device 10, and then perform an operation corresponding to the user's touch input or approach input. For example, the main processor 15 may perform an operation, or execute an application indicated by an icon touched by the user.

In addition, the main processor 15 may receive scanning data from the scanning driving circuit 500, and perform an operation or execute an application based on whether or not the scanning data is valid.

The main processor 15 may be an application processor formed of an integrated circuit, a central processing unit, or a system chip.

The camera 16 may process an image frame of a still image or video obtained by the image sensor in a camera mode, and output the image frame to the main processor 15.

The cable 600 that is passed through the cable hole CAH of the bracket 13 may be connected to the main connector 17. Thus, the main circuit board 14 may be electrically connected to the display circuit board 300.

The battery 18 may be disposed to not overlap with the main circuit board 14 in the third direction DR3. The battery 18 may overlap with the battery hole BH of the bracket 13 in the third direction DR3.

In addition, the main circuit board 14 may be further equipped with a mobile communication module (e.g., a mobile communication circuit or device) capable of transmitting and receiving radio signals with at least one of a base station, an external terminal, or a server in a mobile communication network. The radio signal may include various suitable kinds of data according to transmission and reception of a voice signal, a video call signal, or a text/multimedia message.

The lower cover 12 may be disposed under the main circuit board 14 and the battery 18. The lower cover 12 may be fixed by being fastened to the bracket 13. The lower cover 12 may form the upper side surface, lower side surface, and bottom surface of the electronic device 10. The lower cover 12 may include a plastic, a metal, or both a plastic and a metal.

The lower cover 12 may include a second camera hole CMH2 through which the bottom surface of the camera device 16 is exposed. The position of the camera 16 and the positions of the first and second camera holes CMH1 and CMH2 corresponding to the camera 16 are not limited to those illustrated in FIG. 2.

The display device 100 according to one or more embodiments of the present disclosure will be described in more detail hereinafter.

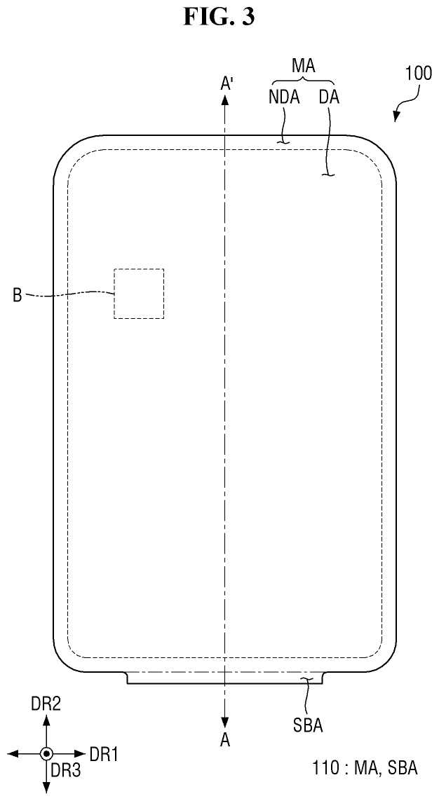

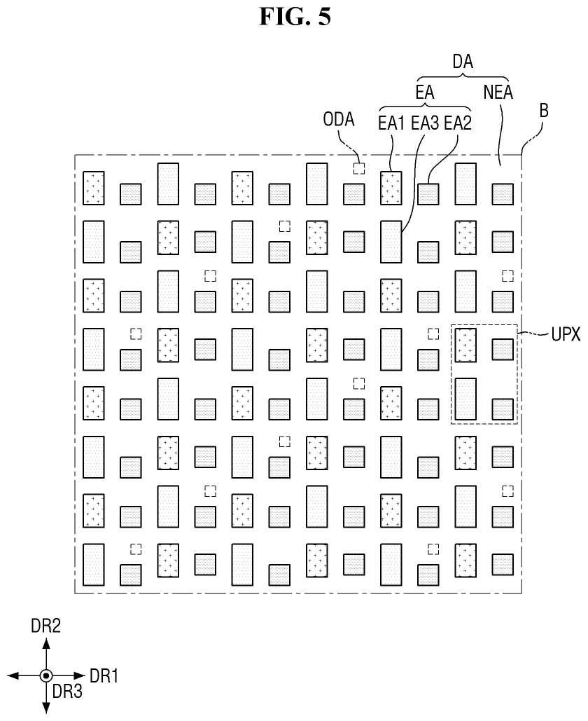

FIG. 3 is a plan view illustrating the display device of FIG. 2. FIG. 4 is a cross-sectional view taken along the line A-A′ of FIG. 3. FIG. 5 is an enlarged layout diagram illustrating the part B of FIG. 3.

FIGS. 3 and 4 illustrate the display device 100 with a part of the sub-region SBA in a bent state.

The display device 100 may be a light emitting display device, such as an organic light emitting display including an organic light emitting diode, a quantum dot light emitting display including a quantum dot light emitting layer, an inorganic light emitting display including an inorganic semiconductor, and a micro light emitting display including a micro or nano light emitting diode (LED). For convenience, the display device 100 will be described in more detail hereinafter in the context of an organic light emitting display device as a representative example. However, the present disclosure is not limited thereto, and the embodiments described herein may be applied to a display device including an organic insulating material, an organic light emitting material, and a metal material.

The display device 100 may be formed to be flat or substantially flat, but the present disclosure is not limited thereto. For example, the display device 100 may include a curved portion formed at left and right ends, and having a constant curvature or a varying curvature. In addition, the display device 100 may be formed to be flexible so that it can be curved, bent, folded, or rolled.

Referring to FIG. 3, at least one surface of the display device 100 includes the main region MA from which light for displaying an image is emitted.

In a plan view, the display area DA may be formed in a rectangular shape having short sides extending in the first direction DR1 and long sides extending in the second direction DR2 crossing the first direction DR1. The corner where the short side extending in the first direction DR1 and the long side extending in the second direction DR2 meet each other may be rounded to have a curvature (e.g., a predetermined curvature) or may be right-angled. The planar shape of the display area DA is not limited to the rectangular shape, and may be formed in another polygonal shape, a circular shape, or an elliptical shape.

The display area DA may occupy most of the main region MA. The display area DA may be disposed at the center of the main region MA.

Referring to FIG. 4, the display device 100 includes the sub-region SBA protruding from one side of the main region MA.

The sub-region SBA may be a region protruding from the non-display area NDA of the main region MA to one side in the second direction DR2.

Because a part of the sub-region SBA is transformed to be bent, another part of the sub-region SBA may be disposed on the rear surface of the display device 100.

The display device 100 according to one or more embodiments includes a substrate 110, a circuit layer 120 disposed on the substrate 110, and an element layer 130 disposed on the circuit layer 120.

According to one or more embodiments, the display device 100 may further include an encapsulation layer 140 disposed on the element layer 130, and the touch sensor layer 150 disposed on the encapsulation layer 140. In addition, the display device 100 may further include a polarization layer 160 disposed on the touch sensor layer 150, in order to reduce a reflection of external light.

The substrate 110 may include the main region MA corresponding to the display surface, and the sub-region SBA protruding from one side of the main region MA in the second direction DR2.

The main region MA of the substrate 110 may include the display area DA at most of the center of the main region MA, and the non-display area NDA at the periphery of the display area DA.

The sub-region SBA may protrude from one side of the main region MA in the second direction DR2.

Referring to FIG. 5, the display area DA includes emission areas EA, a non-emission area NEA that is a separation region between the emission areas EA, and light sensing areas ODA disposed in parts of the non-emission area NEA.

Each of the emission areas EA may be a unit that emits light in a wavelength band corresponding to one color from among two or more different colors having a luminance corresponding to an image signal.

Each of the emission areas EA may have a rhombus planar shape or a rectangular planar shape. However, the present disclosure is not limited thereto, and the planar shapes of the emission areas EA are not limited to those illustrated in FIG. 5. In other words, the emission areas EA may have a polygonal shape, such as a rhombus shape or a hexagonal shape, other than a rectangular shape, a circular shape, or an elliptical shape in a plan view.

The emission areas EA may include a first emission area EA1 for emitting light of a first color having a desired wavelength band (e.g., a predetermined wavelength band), a second emission area EA2 for emitting light of a second color having a wavelength band lower than that of the first color, and a third emission area EA3 for emitting light of a third color having a wavelength band lower than that of the second color.

For example, the first color may be red having a wavelength band of approximately 600 nm to approximately 750 nm, the second color may be green having a wavelength band of approximately 480 nm to approximately 560 nm, and the third color may be blue having a wavelength band of approximately 370 nm to approximately 460 nm. However, the present disclosure is not limited thereto, and the wavelength bands of the first color, the second color, and the third color may be variously modified as needed or desired.

Because the emission areas EA include the first emission area EA1, the second emission area EA2, and the third emission area EA3, each of a plurality of unit pixels UPX may be provided by a combination of one or more first emission areas EA1, one or more second emission areas EA2, and one or more third emission areas EA3 that are adjacent to each other from among the emission areas EA.

Each of the unit pixels UPX may be a unit for displaying various suitable colors including white. In other words, light of various suitable colors displayed by the unit pixels UPX may be implemented as a mixture of the light emitted from two or more emission areas EA included in each unit pixel UPX.

In a case where the first color of the first emission area EA1, the second color of the second emission area EA2, and the third color of the third emission area EA3 are red, green, and blue, respectively, the third emission area EA3 may have a larger size (e.g., a larger width) than that of the first emission area EA1, and the second emission area EA2 may have a smaller size (e.g., a smaller width) than that of the first emission area EA1. However, the present disclosure is not limited thereto, and the widths of the emission areas EA are not limited to those illustrated in FIG. 5.

Further, the first emission areas EA1 and the third emission areas EA3 may be alternately arranged along the second direction DR2. The second emission areas EA2 may be arranged side by side with each other along the second direction DR2, and may be disposed between the first emission areas EA1 and the third emission areas EA3 along the first direction DR1.

In this case, each of the unit pixels UPX may include one first emission area EA1 and one third emission area EA3 that are adjacent to each other in the second direction DR2, and two second emission areas EA2 that are adjacent thereto in the first direction DR1. However, the present disclosure is not limited thereto, and the arrangement pattern of the emission areas EA and the components of the unit pixels UPX are not limited to those illustrated in FIG. 5.

According to one or more embodiments, the display area DA includes the light sensing areas ODA disposed in parts of the non-emission area NEA.

For example, the light sensing areas ODA may be disposed between the second emission areas EA2 having a relatively smaller width, in the second direction DR2. One or more emission areas EA may be disposed between the light sensing areas ODA in each of the first and second directions DR1 and DR2.

As shown in FIG. 4, according to one or more embodiments, the element layer 130 includes light emitting elements LE (e.g., see FIG. 8) respectively disposed in the emission areas EA, and the light sensing elements PD respectively disposed in the light sensing areas ODA.

According to one or more embodiments, as shown in FIG. 7, the circuit layer 120 may include the light emitting pixel drivers EPD respectively electrically connected to the light emitting elements LE of the element layer 130, the light sensing pixel drivers DPD respectively electrically connected to the light sensing elements PD of the element layer 130, the data lines DL electrically connected to the light emitting pixel drivers EPD, and the read-out lines ROL electrically connected to the light sensing pixel drivers DPD.

The encapsulation layer 140 may cover the element layer 130, and may extend into the non-display area NDA to be contact with the circuit layer 120. The encapsulation layer 140 may include a structure in which two or more inorganic layers and at least one organic layer are alternately stacked.

The touch sensor layer 150 may be disposed on the encapsulation layer 140, and may correspond to the main region MA. The touch sensor layer 150 may include touch electrodes for sensing a touch of a user or an object.

The polarization layer 160 blocks external light reflected from the touch sensor layer 150, the encapsulation layer 140, the element layer 130, the circuit layer 120, and/or the interfaces thereof, to prevent or substantially prevent deterioration of a visibility of an image due to external light reflection.

Because a part of the sub-region SBA is transformed into a bent shape, the display driving circuit 200 mounted in the sub-region SBA and the display circuit board 300 connected to one side of the sub-region SBA may be disposed under the substrate 110.

The display driving circuit 200 may be electrically connected to the data lines DL of the circuit layer 120. The display driving circuit 200 may transmit the data signals for the light emitting pixel drivers EPD to the data lines DL based on control signals and power voltages supplied from the display circuit board 300.

The display driving circuit 200 may be provided as an integrated circuit (IC), and may be mounted on the sub-region SBA of the display device 100 by a chip on glass (COG) method, a chip on plastic (COP) method, or an ultrasonic method. However, the present disclosure is not limited thereto. For example, the display driving circuit 200 may be mounted on the display circuit board 300.

One end of the display circuit board 300 may be attached onto pads disposed on one edge of the sub-region SBA of the display device 100 by using an anisotropic conductive film.

The display circuit board 300 may be a flexible printed circuit board (FPCB) that is bendable, a rigid printed circuit board (PCB) that maintains a flat or substantially flat shape, or a composite printed circuit board having both of the rigid printed circuit board and the flexible printed circuit board.

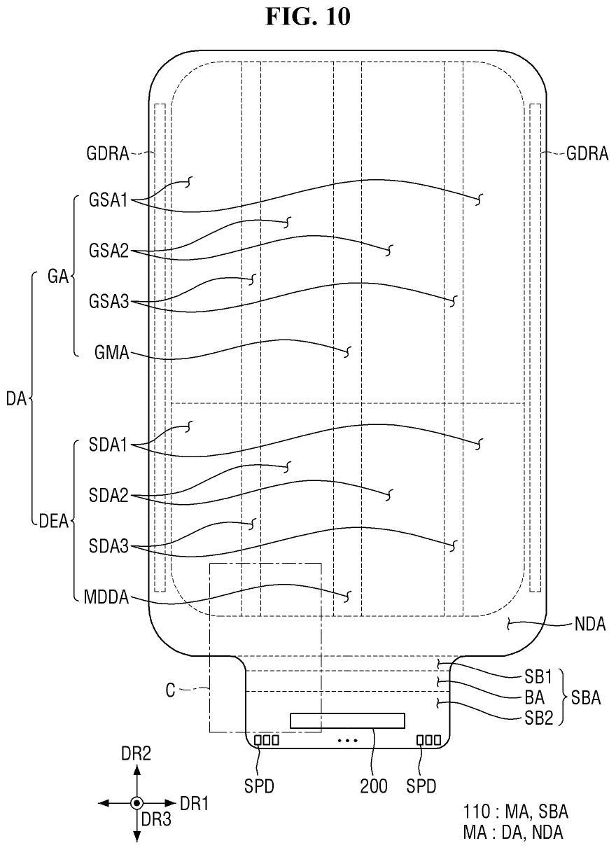

The display circuit board 300 may be connected to signal pads SPD (e.g., see FIG. 10) disposed on one side of the sub-region SBA.

The touch driving circuit 400 and the scanning driving circuit 500 may be mounted on the display circuit board 300.

The touch driving circuit 400 may be electrically connected to the touch sensor layer 150 of the display device 100.

The touch driving circuit 400 may apply a touch driving signal to driving lines of the touch sensor layer 150, and may receive a touch sensing signal from sensing lines. Further, the touch driving circuit 400 may detect charge variation amounts of capacitances based on the touch sensing signal, thereby determining whether or not a user has touched or approached. The user's touch may refer to an object, such as a pen or the user's finger, that is in direct contact with the top surface of the cover window disposed on the touch sensor layer. The user's approach may refer to the object, such as the pen or the user's finger, that hovers over the top surface of the cover window at a suitable distance (e.g., a predetermined distance). The touch driving circuit 400 may output touch data including the user's touch coordinates to the main processor 15.

The scanning driving circuit 500 may be electrically connected to the read-out lines ROL of the circuit layer 120.

The scanning driving circuit 500 may collect light sensing signals of the light sensing elements PD disposed in the light sensing areas ODA of the main region MA through the light sensing pixel drivers DPD and the read-out lines ROL. Further, based on the collected light sensing signals, the scanning driving circuit 500 may output, to the main processor 15, scanning data about the shape of an object in contact with a screen by detecting differences in the amount of light reflected by the object in contact with the screen.

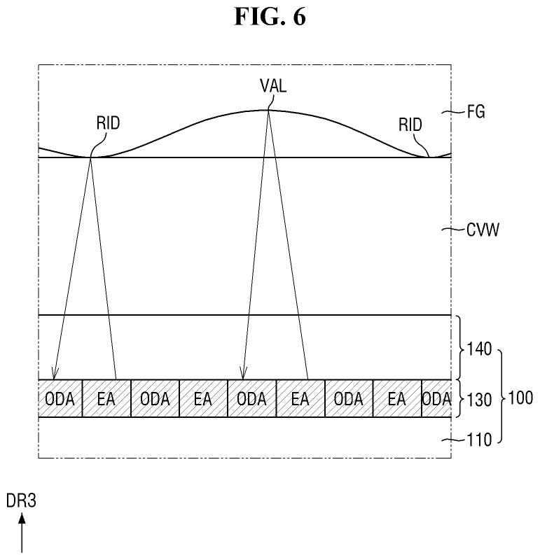

FIG. 6 is a diagram illustrating a scanning function by the light sensing areas shown in FIG. 5.

Referring to FIG. 6, the display device 100 according to one or more embodiments may include the light sensing elements PD disposed in the light sensing areas ODA, and thus, may provide a scanning function to detect the shape of an object in contact with the screen.

The fingerprint of a user's finger FG in contact with the cover window 11 includes ridges RID, and valleys VAL between the ridges RID. The ridges RID in the fingerprint are in contact with the cover window 11. However, the valleys VAL in the fingerprint are spaced apart from the cover window 11. In other words, the top surface of the cover window 11 facing the valleys VAL is in contact with air.

Light emitted from the emission areas EA may be reflected by the user's finger FG that is in contact with the cover window 11, and may be detected by the light sensing elements PD of the light sensing areas ODA. However, because the refractive index of the finger FG is different from that of air, the amount of light reflected from the ridge RID may be different from the amount of light reflected from the valley VAL.

Accordingly, based on the difference in the amount of light incident on the light sensing elements PD, the ridge RID and the valley VAL of the fingerprint may be derived, so that a pattern of the fingerprint of the finger FG may be detected.

FIG. 7 is a block diagram of the circuit layer of FIG. 4.

Referring to FIG. 7, the circuit layer 120 of the display device 100 according to one or more embodiments may include the light emitting pixel drivers EPD respectively corresponding to the emission areas EA of the display area DA, the light sensing pixel drivers DPD respectively corresponding to the light sensing areas ODA of the display area DA, the data lines DL electrically connected to the light emitting pixel drivers EPD, and the read-out lines ROL electrically connected to the light sensing pixel drivers DPD.

The display device 100 according to one or more embodiments may include the display driving circuit (e.g., a data driver) 200 that transmits the data signals Vdata (e.g., see FIG. 8) for the light emitting pixel drivers EPD to the data lines DL, and the scanning driving circuit (e.g., a read-out IC) 500 that collects the light sensing signals of the light sensing pixel drivers DPD through the read-out lines ROL.

The display device 100 according to one or more embodiments may further include a gate driving circuit (e.g., a gate driver) 101 that supplies one or more gate signals to the light emitting pixel drivers EPD and the light sensing pixel drivers DPD, an emission control circuit (e.g., an emission driver) 102 that supplies emission control signals EC (e.g., see FIG. 8) to the light emitting pixel drivers EPD, a power supply unit (e.g., a power supply, a power supply circuit, or a power supply device) 700 that supplies various suitable power and voltages to the light emitting pixel drivers EPD and the light sensing pixel drivers DPD, and a timing controller 800 that controls a drive timing.

The timing controller 800 receives an image signal supplied from the outside of the display device 100. The timing controller 800 may output image data DATA and a data control signal DCS to the display driving circuit 200. In addition, the timing controller 800 may generate a scan control signal SCS for controlling the operation timing of the gate driving circuit 101, and an emission control driving signal ECS for controlling the operation timing of the emission control circuit 102. For example, the timing controller 800 may generate the scan control signal SCS and the emission control driving signal ECS, output the scan control signal SCS to the gate driving circuit 101 through a scan control line, and output the emission control driving signal ECS to the emission control circuit 102 through an emission control driving line.

The display driving circuit 200 may convert the image data DATA into analog data voltages, and may output the analog data voltages to the data lines DL.

The gate driving circuit 101 may generate gate signals in response to the scan control signal SCS, and may sequentially output the gate signals to gate lines GL. As shown in FIG. 8, the gate lines GL may include a scan write line GWL for transmitting a scan write signal GW, a scan initialization line GIL for transmitting a scan initialization signal GI, a gate control line GCL for transmitting a gate control signal GC, a bias control line GBL for transmitting a bias control signal GB, and a reset control line GRL for transmitting a reset control signal GR.

The emission control circuit 102 may sequentially output the emission control signals EC (e.g., see FIG. 8) to the emission control lines ECL in response to the emission control driving signal ECS. The emission control signals EC of the emission control circuit 102 may have pulses of a first level voltage or a second level voltage. In some embodiments, the emission control circuit 102 may not be provided separately from the gate driving circuit 101, and may be incorporated together with the gate driving circuit 101.

The power supply unit 700 may supply various suitable kinds of power used to drive the light emitting pixel drivers EPD and the light sensing pixel drivers DPD.

For example, as shown in FIG. 8, the power supply unit 700 may supply a first power ELVDD and a second power ELVSS for driving the light emitting elements LE, and a first initialization power VINT and a second initialization power VAINT for initializing the light emitting pixel drivers EPD.

In addition, the power supply unit 700 may further supply a reset voltage VRST (e.g., see FIG. 8) for resetting the light sensing pixel drivers DPD.

The scanning driving circuit 500 may be electrically connected to the light sensing elements PD through the read-out lines ROL and the light sensing pixel drivers DPD.

Each of the light sensing elements PD may generate a photocurrent

corresponding to the amount of light incident on the light sensing element PD. The scanning driving circuit 500 may detect the shape of a user's fingerprint based on the photocurrent of each of the light sensing elements PD.

The scanning driving circuit 500 may generate scanning data depending on the magnitude of the photocurrent detected by the light sensing elements PD, and may transmit the scanning data to the main processor. The main processor 15 may compare the scanning data with reference data, and may execute an application based on whether or not the scanning data matches the user's fingerprint.

FIG. 8 is an equivalent circuit diagram of the light emitting pixel driver and the light sensing pixel driver shown in FIG. 7.

Referring to FIG. 8, one of the light emitting elements LE of the element layer 130 may be electrically connected between one of the light emitting pixel drivers EPD of the circuit layer 120 and the second power ELVSS.

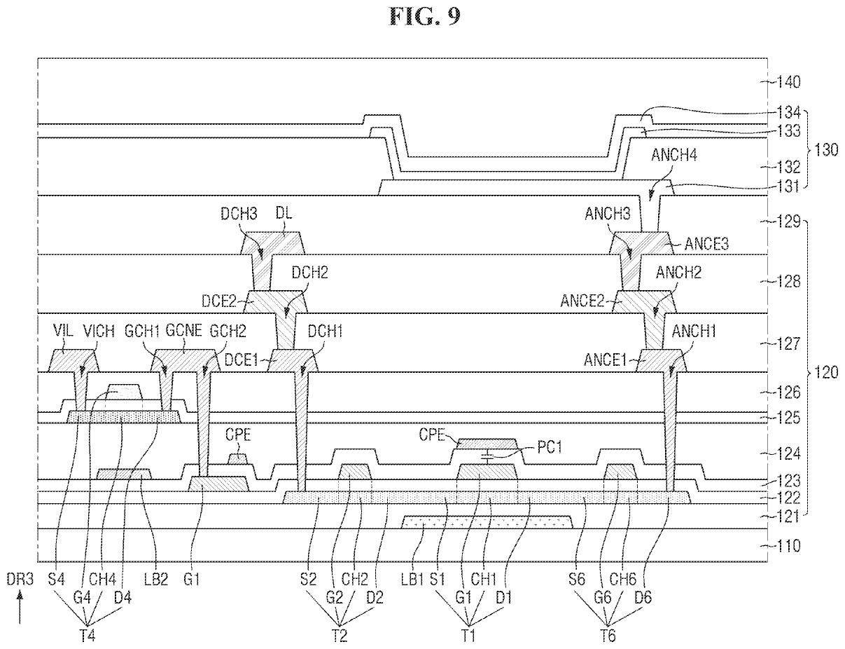

In other words, an anode electrode 131 (e.g., see FIG. 9) of the light emitting element LE may be electrically connected to the light emitting pixel driver EPD, and a cathode electrode 134 of the light emitting element LE may be applied with the second power ELVSS, which may have a lower voltage level than that of the first power ELVDD.

A capacitor Cel connected in parallel with the light emitting element LE in FIG. 8 may refer to (e.g., may represent) a parasitic capacitance between the anode electrode 131 and the cathode electrode 134 of the light emitting element LE.

The circuit layer 120 may further include a first power line VDL for transmitting the first power ELVDD, a first initialization power line VIL for transmitting a first initialization power VINT, a second initialization power line VAIL for transmitting a second initialization power VAINT, and a bias power line VBL for transmitting a bias power VBS.

The circuit layer 120 may include a scan write line GWL for transmitting a scan write signal GW, a scan initialization line GIL for transmitting a scan initialization signal GI, an emission control line ECL for transmitting an emission control signal EC, a gate control line GCL for transmitting a gate control signal GC, and a bias control line GBL for transmitting a bias control signal GB.

One light emitting pixel driver EPD of the circuit layer 120 may include a first transistor T1 that generates a driving current for driving the light emitting element LE, two or more transistors T2 to T8 electrically connected to the first transistor T1, and at least one capacitor PC1.

The first transistor T1 is connected in series with the light emitting element LE between the first power ELVDD and the second power ELVSS.

In other words, the first electrode (e.g., the source electrode) of the first transistor T1 may be electrically connected to the first power line VDL through the fifth transistor T5. Further, the second electrode (e.g., the drain electrode) of the first transistor T1 may be electrically connected to the anode electrode 131 of the light emitting element LE through the sixth transistor T6.

The first electrode of the first transistor T1 may be electrically connected to the data line DL through the second transistor T2.

The gate electrode of the first transistor T1 may be electrically connected to the first power line VDL through the first capacitor PC1. In other words, the first capacitor PC1 may be electrically connected between the gate electrode of the first transistor T1 and the first power line VDL.

Accordingly, the potential of the gate electrode of the first transistor T1 may be maintained or substantially maintained by the first power ELVDD of the first power line VDL.

Further, when the data signal Vdata of the data line DL is transmitted to the first electrode of the first transistor T1 through the turned-on second transistor T2, a voltage difference corresponding to the data signal Vdata and the first power ELVDD may be generated between the gate electrode of the first transistor T1 and the first electrode of the first transistor T1.

In this case, when the voltage difference between the gate electrode of the first transistor T1 and the first electrode of the first transistor T1 (e.g., the gate-to-source voltage difference) becomes equal to or greater than a threshold voltage, the first transistor T1 may be turned on to generate a drain-to-source current of the first transistor T1 corresponding to the data signal Vdata.

Then, when the fifth transistor T5 and the sixth transistor T6 are turned on, the first transistor T1 may be connected in series with the light emitting element LE between the first power line VDL and the second power ELVSS. Accordingly, the drain-to-source current of the first transistor T1 corresponding to the data signal Vdata may be supplied as a driving current for the light emitting element LE.

Accordingly, the light emitting element LE may emit light having a desired luminance corresponding to the data signal Vdata.

The second transistor T2 may be electrically connected between the first electrode of the first transistor T1 and the data line DL. The second transistor T2 may be turned on by the scan write signal GW of the scan write line GWL.

The third transistor T3 may be electrically connected between the gate electrode of the first transistor T1 and the second electrode of the first transistor T1. The third transistor T3 may be turned on by the gate control signal GC of the gate control line GCL.

The fourth transistor T4 may be connected between the gate electrode of the first transistor T1 and the first initialization power line VIL. The fourth transistor T4 may be turned on by the scan initialization signal GI of the scan initialization line GIL.

The third transistor T3 and the fourth transistor T4 may be provided as N-type MOSFETs (e.g., NMOS transistors).

The fifth transistor T5 may be electrically connected between the first electrode of the first transistor T1 and the first power line VDL.

The sixth transistor T6 may be electrically connected between the second electrode of the first transistor T1 and the anode electrode 131 of the light emitting element LE.

The fifth transistor T5 and the sixth transistor T6 may be turned on by the emission control signal EC of the emission control line ECL.

A seventh transistor T7 may be electrically connected between the anode electrode 131 of the light emitting element LE and the second initialization power line VAIL. The seventh transistor T7 may be turned on by the bias control signal GB of the bias control line GBL.

The eighth transistor T8 may be connected between the first electrode of the first transistor T1 and the bias power line VBL.

The eighth transistor T8 may be turned on by the bias control signal GB of the bias control line GBL.

From among the first to eighth transistors T1 to T8, the first, second, and fifth to eighth transistors T1, T2, and T5 to T8, except for the third and fourth transistor T3 and T4, may be provided as P-type MOSFETs (e.g., PMOS transistors).

One of the light sensing elements PD of the element layer 130 may be electrically connected between an element output node NOP of one of the light sensing pixel drivers DPD of the circuit layer 120 and the second power ELVSS.

The circuit layer 120 may further include the reset control line GRL for transmitting the reset control signal GR to initiate a reset of the light sensing pixel drivers DPD, a reset voltage line VRL for transmitting the reset voltage VRST to reset the light sensing pixel drivers DPD, and the read-out line ROL electrically connecting the light sensing pixel drivers DPD to the scanning driving circuit 500.

Each of the light sensing pixel drivers DPD may include at least one transistor T9, T10, T11.

The light sensing element PD may be a photoelectric conversion element that converts incident light into an electrical signal by generating a photocurrent corresponding to the amount of the incident light, and may output a light sensing signal.

The light sensing element PD may be a photodiode including a sensing anode electrode, a sensing cathode electrode, and a photoelectric conversion layer disposed between the sensing anode electrode and the sensing cathode electrode.

The light sensing element PD may be a phototransistor or an inorganic photodiode formed of a p-n type or p-i-n type inorganic material. As another example, the photoelectric conversion element PD may be an organic photodiode including an electron donating material for generating donor ions, and an electron accepting material for generating acceptor ions.

When light is incident on the light sensing element PD, the photoelectric conversion layer may react to the incident light to generate photocharges, and the photocharges generated in the photoelectric conversion layer may move, thereby generating a photocurrent between the sensing anode electrode and the sensing cathode electrode.

As an example, photocharges generated in the photoelectric conversion layer by light incident on the light sensing element PD may be accumulated in the sensing anode electrode. In addition, the potential of the element output node NOP that is electrically connected to the sensing anode electrode may be increased by the photocharges accumulated in the sensing anode electrode. When the light sensing element PD and the read-out line ROL are connected to the element output node NOP by the turned-on ninth and eleventh transistors T9 and T11, a sensing voltage may be accumulated at a node N3 between the read-out line ROL and the eleventh transistor T11 in proportion to the voltage of the element output node NOP where charges are accumulated.

The ninth transistor T9 may include a gate electrode electrically connected to the element output node NOP, and the ninth transistor T9 may be electrically connected between the second initialization power line VAIL and the eleventh transistor T11.

The ninth transistor T9 may be a source follower amplifier that generates a source-drain current in proportion to the amount of electric charges of the element output node NOP that is input to the gate electrode thereof.

In other words, when the potential of the element output node NOP is increased by the photocharges accumulated in the light sensing element PD, and a difference voltage between the second initialization power VAINT and the potential of the element output node NOP becomes equal to or greater than the threshold voltage of the ninth transistor T9, the ninth transistor T9 may be turned on. In this case, a light sensing signal corresponding to the difference voltage between the second initialization power VAINT and the potential of the element output node NOP may be generated by the turned-on ninth transistor T9.

Although FIG. 8 illustrates that the first electrode of the ninth transistor T9 is connected to the second initialization power line VAIL, the present disclosure is not limited thereto. For example, the first electrode of the ninth transistor T9 may be connected to one of the first power line VDL or the first initialization power line VIL, instead of to the second initialization power line VAIL.

The tenth transistor T10 may be electrically connected between the element output node NOP and the reset voltage line VRL, and may be turned on by the reset control signal GR of the reset control line GRL. When the tenth transistor T10 is turned on by the reset control signal GR, the potential of the element output node NOP may be reset to the reset voltage VRST of the reset voltage line VRL.

The eleventh transistor T11 may be electrically connected between the second electrode of the ninth transistor T9 and the read-out line ROL, and may be turned on by the scan write signal GW of the scan write line GWL. Accordingly, the source-drain current (e.g., the light sensing signal) of the ninth transistor T9 may be transmitted to the read-out line ROL through the eleventh transistor T11 that is turned on by the scan write signal GW.

The ninth transistor T9 and the eleventh transistor T11 may be provided as P-type MOSFETs (e.g., PMOS transistors), and the tenth transistor T10 may be provided as an N-type MOSFET (e.g., an NMOS transistor).

FIG. 9 is a cross-sectional view illustrating the first transistor, the second transistor, the fourth transistor, the sixth transistor, and the light emitting element of FIG. 8.

Referring to FIG. 9, the circuit layer 120 of the display device 100 according to one or more embodiments may include a buffer layer 121 that covers a first light blocking layer LB1 on the substrate 110, a first semiconductor layer CH1, S1, D1, CH2, S2, D2, CH6, S6, and D6 disposed on the buffer layer 121, a first gate insulating layer 122 that covers the first semiconductor layer CH1, S1, D1, CH2, S2, D2, CH6, S6, and D6, a first gate conductive layer G1, G2, and G6 disposed on the first gate insulating layer 122, a second gate insulating layer 123 that covers the first gate conductive layer G1, G2, and G6, a second gate conductive layer CPE and LB2 disposed on the second gate insulating layer 123, a first interlayer insulating layer 124 that covers the second gate conductive layer CPE and LB2, a second semiconductor layer CH4, S4, and D4 disposed on the first interlayer insulating layer 124, a third gate insulating layer 125 that covers the second semiconductor layer CH4, S4, and D4, a third gate conductive layer G4 disposed on the third gate insulating layer 125, a second interlayer insulating layer 126 that covers the third gate conductive layer G4, a first source/drain conductive layer ANCE1, DCE1, GCNE, and VIL disposed on the second interlayer insulating layer 126, a first planarization layer 127 that covers the first source/drain conductive layer ANCE1, DCE1, GCNE, and VIL, a second source/drain conductive layer ANCE2 and DCE2 disposed on the first planarization layer 127, a second planarization layer 128 that covers the second source/drain conductive layer ANCE2 and DCE2, and a third source/drain conductive layer ANCE3 and DL disposed on the second planarization layer 128.

The first transistor T1 may include a channel portion CH1, a source portion S1, and a drain portion D1 formed of the first semiconductor layer on the buffer layer 121, and a gate electrode G1 disposed on the first gate insulating layer 122 and overlapping with the channel portion CH1.

The channel portion CH1 of the first transistor T1 may overlap with the first light blocking layer LB1 on the substrate 110.

The second transistor T2 may include a channel portion CH2, a source portion S2, and a drain portion D2 formed of the first semiconductor layer on the buffer layer 121, and a gate electrode G2 disposed on the first gate insulating layer 122 and overlapping with the channel portion CH2.

The sixth transistor T6 may include a channel portion CH6, a source portion S6, and a drain portion D6 formed of the first semiconductor layer on the buffer layer 121, and a gate electrode G6 disposed on the first gate insulating layer 122 and overlapping with the channel portion CH6.

The source portion S2 of the second transistor T2 may be electrically connected to the data line DL through a first data connection electrode DCE1 and a second data connection electrode DCE2.

The first data connection electrode DCE1 may be disposed on the second interlayer insulating layer 126, and may be electrically connected to the source portion S2 of the second transistor T2 through a first data connection hole DCH1 penetrating the second interlayer insulating layer 126, the third gate insulating layer 125, the first interlayer insulating layer 124, the second gate insulating layer 123, and the first gate insulating layer 122.

The second data connection electrode DCE2 may be disposed on the first planarization layer 127, and may be electrically connected to the first data connection electrode DCE1 through a second data connection hole DCH2 penetrating the first planarization layer 127.

The data line DL may be disposed on the second planarization layer 128, and may be electrically connected to the second data connection electrode DCE2 through a third data connection hole DCH3 penetrating the second planarization layer 128.

The drain portion D2 of the second transistor T2 may be connected to the source portion S1 of the first transistor T1.

The drain portion D1 of the first transistor T1 may be connected to the source portion S6 of the sixth transistor T6.

The drain portion D6 of the sixth transistor T6 may be electrically connected to the anode electrode 131 through a first anode connection electrode ANCE1, a second anode connection electrode ANCE2, and a third anode connection electrode ANCE3.

The first anode connection electrode ANCE1 may be disposed on the second interlayer insulating layer 126, and may be electrically connected to the drain portion D6 of the sixth transistor T6 through a first anode connection hole ANCH1 penetrating the second interlayer insulating layer 126, the third gate insulating layer 125, the first interlayer insulating layer 124, the second gate insulating layer 123, and the first gate insulating layer 122.

The second anode connection electrode ANCE2 may be disposed on the first planarization layer 127, and may be electrically connected to the first anode connection electrode ANCE1 through a second anode connection hole ANCH2 penetrating the first planarization layer 127.

The third anode connection electrode ANCE3 may be disposed on the second planarization layer 128, and may be electrically connected to the second anode connection electrode ANCE2 through a third anode connection hole ANCH3 penetrating the second planarization layer 128.

The anode electrode 131 may be disposed on a third planarization layer 129, and may be electrically connected to the third anode connection electrode ANCE3 through a fourth anode connection hole ANCH4 penetrating the third planarization layer 129.

The first capacitor PC1 may be provided by an overlapping region between a capacitor electrode CPE disposed on the second gate insulating layer 123 and the gate electrode G1 of the first transistor T1.

The fourth transistor T4 may include a channel portion CH4, a source portion S4, and a drain portion D4 formed of the second semiconductor layer on the first interlayer insulating layer 124, and a gate electrode G4 disposed on the third gate insulating layer 125 and overlapping with the channel portion CH4.

The channel portion CH4 of the fourth transistor T4 may overlap with a second light blocking layer LB2 on the second gate insulating layer 123.

The source portion S4 of the fourth transistor T4 may be electrically connected to the first initialization power line VIL on the second interlayer insulating layer 126 through a hole VICH penetrating the second interlayer insulating layer 126 and the third gate insulating layer 125.

The drain portion D4 of the fourth transistor T4 may be electrically connected to the gate electrode G1 of the first transistor T1 through a gate connection electrode GCNE on the second interlayer insulating layer 126.

The gate connection electrode GCNE may be electrically connected to the drain portion D4 of the fourth transistor T4 through a first gate connection hole GCH1 penetrating the second interlayer insulating layer 126 and the third gate insulating layer 125.

The gate connection electrode GCNE may be electrically connected to the gate electrode G1 of the first transistor T1 through a second gate connection hole GCH2 penetrating the second interlayer insulating layer 126, the third gate insulating layer 125, the first interlayer insulating layer 124, and the second gate insulating layer 123.

Because the third transistor T3 and the tenth transistor T10 are the same or substantially the same (or similar) in structure to that of the fourth transistor T4, and the fifth transistor T5, the seventh transistor T7, the ninth transistor T9, and the eleventh transistor T11 are the same or substantially the same (or similar) in structure to those of the second transistor T2 and the sixth transistor T6, redundant description thereof may not be repeated.

In addition, the circuit layer 120 of the display device 100 according to one or more embodiments may further include a wire electrically connected between some of the data lines DL and the display driving circuit 200, and disposed in the display area DA, and a wire electrically connected between some of the read-out lines ROL and the scanning driving circuit 500, and disposed in the display area DA, in order to reduce the width of the non-display area NDA.

FIG. 10 is a plan view illustrating the substrate of FIG. 2 according to one or more embodiments.

Referring to FIG. 10, the substrate 110 of the display device 100 according to one or more embodiments may include the main region MA corresponding to the display surface, and the sub-region SBA protruding from one side of the main region MA.

The main region MA may include the display area DA disposed at most of the center of the main region MA, and the non-display area NDA disposed at the edge to surround (e.g., around a periphery of) the display area DA.

The display area DA may include a bypass area DEA disposed on one side that is adjacent to the sub-region SBA, and a general area GA disposed on the remaining area of the display area DA excluding the bypass area DEA.

The bypass area DEA may include a bypass middle area MDDA disposed at the center in the first direction DR1, a first bypass side area SDA1 parallel to or substantially parallel to the bypass middle area MDDA in the first direction DR1 and in contact with the non-display area NDA, a second bypass side area SDA2 disposed between the bypass middle area MDDA and the first bypass side area SDA1, and a third bypass side area SDA3 disposed between the first bypass side area SDA1 and the second bypass side area SDA2.

The first bypass side area SDA1 may be disposed to be closer to a bent corner of the substrate 110 than the bypass middle area MDDA, the second bypass side area SDA2, and the third bypass side area SDA3.

The first bypass side area SDA1, the third bypass side area SDA3, and the second bypass side area SDA2 may be disposed between one side of the bypass middle area MDDA in the first direction DR1 and the non-display area NDA, and between another side of the bypass middle area MDDA in the first direction DR1 and the non-display area NDA.

The general area GA may include a general middle area GMA connected to the bypass middle area MDDA of the bypass area DEA in the second direction DR2, a first general side area GSA1 connected to the first bypass side area SDA1 in the second direction DR2, a second general side area GSA2 connected to the second bypass side area SDA2 in the second direction DR2, and a third general side area GSA3 connected to the third bypass side area SDA3 in the second direction DR2.

The non-display area NDA may include a gate driving circuit area GDRA, in which the gate driving circuit 101 and the emission control circuit 102 are disposed.

The gate driving circuit area GDRA may be disposed in a portion of the non-display area NDA adjacent to at least one side of the display area DA in the first direction DR1.

The sub-region SBA may include a bending region BA that is transformed into a bending shape, a first sub-region SB1 disposed between one side of the bending region BA and the main region MA, and a second sub-region SB2 connected to another side (e.g., an opposite side) of the bending region BA.

When the bending region BA is transformed into a bending shape, the second sub-region SB2 is disposed under the substrate 110 and overlaps with the main region MA.

The display driving circuit 200 may be disposed in the second sub-region SB2.

The signal pads SPD bonded to the circuit board 300 may be disposed at one edge of the second sub-region SB2.

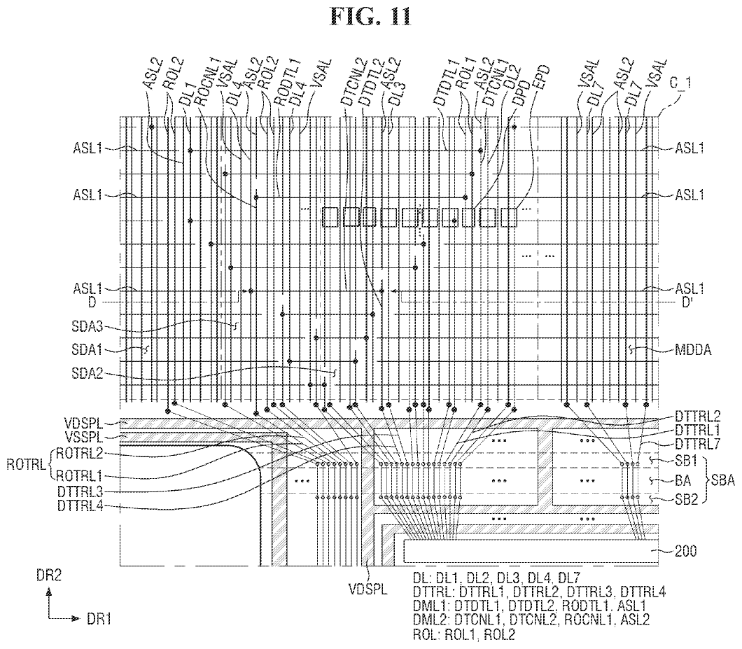

FIG. 11 is an enlarged layout diagram illustrating the part C of FIG. 10 according to an embodiment.

Referring to FIG. 11, the circuit layer 120 of the display device 100 according to one or more embodiments may include the light emitting pixel drivers EPD respectively electrically connected to the light emitting elements LE of the element layer 130, the light sensing pixel drivers DPD respectively electrically connected to the light sensing elements PD of the element layer 130, the data lines DL electrically connected to the light emitting pixel drivers EPD to transmit the data signals Vdata, the read-out lines ROL parallel to or substantially parallel to the data lines DL and electrically connected to the light sensing pixel drivers DPD to transmit the light sensing signals, first dummy lines DML1 extending in the first direction DR1 crossing the data lines DL, and second dummy lines DML2 extending in the second direction DR2 parallel to or substantially parallel to the data lines DL and respectively paired with the data lines DL.

The data lines DL, the read-out lines ROL, and the second dummy lines DML2 may extend in the second direction DR2.

According to one or more embodiments, the first dummy lines DML1 may include a first read-out bypass line RODTL1 electrically connected to a first read-out line ROL1 from among the read-out lines ROL. The second dummy lines DML2 may include a first read-out connection line ROCNL1 electrically connected to the first read-out bypass line RODTL1.

According to one or more embodiments, the circuit layer 120 may further include read-out transmission lines ROTRL disposed in the non-display area NDA.

The read-out transmission lines ROTRL may be electrically connected between the scanning driving circuit 500 and the read-out lines ROL.

From among the read-out transmission lines ROTRL, a first read-out transmission line ROTRL1 for transmitting the signal of the first read-out line ROL1 may be electrically connected to the first read-out line ROL1 through the first read-out connection line ROCNL1 and the first read-out bypass line RODTL1.

In other words, according to one or more embodiments, the first read-out transmission line ROTRL1 may be electrically connected to the first read-out line ROL1 by detouring to the first read-out connection line ROCNL1 and the first read-out bypass line RODTL1 disposed in the bypass area DEA of the display area DA, rather than being directly electrically connected to the first read-out line ROL1.

Thus, the first read-out transmission line ROTRL1 may extend to the first read-out connection line ROCNL1 of the third bypass side area SDA3, rather than to the first read-out line ROL1 of the second bypass side area SDA2, thereby having a relatively smaller extension length. Therefore, the width of the non-display area NDA may be reduced.

The third bypass side area SDA3 may be adjacent to a part of the non-display area NDA where the read-out transmission lines ROTRL are clustered.

In other words, the read-out transmission lines ROTRL may extend to at least a part of the third bypass side area SDA3 and the first bypass side area SDA1 adjacent thereto.

According to one or more embodiments, the read-out lines ROL may further include a second read-out line ROL2 disposed in the third bypass side area SDA3.

From among the read-out transmission lines ROTRL, a second read-out transmission line ROTRL2 for transmitting the signal of the second read-out line ROL2 may be directly electrically connected to the second read-out line ROL2.

In other words, the read-out transmission lines ROTRL may extend to the third bypass side area SDA3. In addition, the second read-out line ROL2 of the third bypass side area SDA3 may be directly electrically connected to the second read-out transmission line ROTRL2.

On the other hand, the first read-out line ROL1 disposed in the second bypass side area SDA2 may be electrically connected to the first read-out transmission line ROTRL1 through the first read-out connection line ROCNL1 and the first read-out bypass line RODTL1 disposed in the bypass area DEA, rather than being directly electrically connected to the first read-out transmission line ROTRL1 extending to the third bypass side area SDA3.

As such, the read-out transmission lines ROTRL may be clustered in a part of the non-display area NDA adjacent to the third bypass side area SDA3. As a result, the total extension length of the read-out transmission lines ROTRL may be reduced, and the area used for arranging the read-out transmission lines ROTRL may be reduced, so that the width of the non-display area NDA may be reduced.

According to an embodiment, some of the read-out transmission lines ROTRL may extend to at least a part of the first bypass side area SDA1 adjacent to the third bypass side area SDA3.

In other words, the second read-out line ROL2 may be disposed in the third bypass side area SDA3, as well as in at least a part of the first bypass side area SDA1 adjacent to the third bypass side area SDA3.

According to one or more embodiments, the data lines DL may include a first data line DL1 disposed in the first bypass side area SDA1, a second data line DL2 and a third data line DL3 disposed in the second bypass side area SDA2, and a fourth data line DL4 disposed in the third bypass side area SDA3.

The first dummy lines DML1 may further include a first data bypass line DTDTL1 electrically connected to the first data line DL1 of the first bypass side area SDA1, and a second data bypass line DTDTL2 electrically connected to the fourth data line DL4 of the third bypass side area SDA3.

The second dummy lines DML2 may further include a first data connection line DTCNL1 paired with the second data line DL2 of the second bypass side area SDA2 and electrically connected to the first data bypass line DTDTL1, and a second data connection line DTCNL2 paired with the third data line DL3 of the second bypass side area SDA2 and electrically connected to the second data bypass line DTDTL2.

From among the bypass lines for electrically connecting the first read-out line ROL1 to the first read-out transmission line ROTRL1, the first read-out connection line ROCNL1 in the second direction DR2 may be paired with the fourth data line DL4 of the third bypass side area SDA3.

According to one or more embodiments, the circuit layer 120 may further include data transmission lines DTTRL disposed in the non-display area NDA.

The data transmission lines DTTRL may be electrically connected between the display driving circuit 200 and the data lines DL.

The data transmission lines DTTRL may extend to the second bypass side area SDA2 and the bypass middle area MDDA. In other words, the data transmission lines DTTRL may be spaced apart from the first bypass side area SDA1 adjacent to the bent corner of the substrate 110, and the third bypass side area SDA3 to which the read-out transmission lines ROTRL extend.

According to one or more embodiments, the second data line DL2 and the third data line DL3 disposed in the second bypass side area SDA2 may be directly electrically connected to the data transmission lines DTTRL, respectively.

On the other hand, the first data line DL1 of the first bypass side area SDA1 and the fourth data line DL4 of the third bypass side area SDA3 may be respectively electrically connected to the data transmission lines DTTRL through the bypass lines disposed in the bypass area DEA, rather than being directly electrically connected to the data transmission lines DTTRL.

In other words, from among the data transmission lines DTTRL, a first data transmission line DTTRL1 for transmitting the data signal of the first data line DL1 of the first bypass side area SDA1 may be electrically connected to the first data line DL1 through the first data connection line DTCNL1 of the second bypass side area SDA2 and the first data bypass line DTDTL1.

From among the data transmission lines DTTRL, a second data transmission line DTTRL2 for transmitting the data signal of the second data line DL2 of the second bypass side area SDA2 may be directly electrically connected to the second data line DL2.

From among the data transmission lines DTTRL, a third data transmission line DTTRL3 for transmitting the data signal of the third data line DL3 of the second bypass side area SDA2 may be directly electrically connected to the third data line DL3.

From among the data transmission lines DTTRL, a fourth data transmission line DTTRL4 for transmitting the data signal of the fourth data line DL4 of the third bypass side area SDA3 may be electrically connected to the fourth data line DL4 through the second data connection line DTCNL2 of the second bypass side area SDA2 and the second data bypass line DTDTL2.

As such, the data transmission lines DTTRL may be clustered in a part of the non-display area NDA parallel to or substantially parallel to the second bypass side area SDA2.

In comparison, the read-out transmission lines ROTRL may be clustered in a part of the non-display area NDA adjacent to the third bypass side area SDA3.

In other words, the clustered area of the data transmission lines DTTRL and the clustered area of the read-out transmission lines ROTRL may be spaced apart from each other in the first direction DR1. Therefore, the read-out transmission lines ROTRL may be provided in the same layer as that of the data transmission lines DTTRL. Accordingly, the layout of the data transmission lines DTTRL and the read-out transmission lines ROTRL may be more easily designed.

In addition, the total extension length of the data transmission lines DTTRL may be reduced, and the area used for arranging the data transmission lines DTTRL may be reduced, so that the width of the non-display area NDA may be reduced.

Further, because the data transmission lines DTTRL may not extend to the first bypass side area SDA1 that is adjacent to the bent corner of the substrate 110, the width of a part of the non-display area NDA adjacent to the bent corner of the substrate 110 may be reduced.

The data lines DL may further include a seventh data line DL7 disposed in the bypass middle area MDDA.

Because the data transmission lines DTTRL extend to the second bypass side area SDA2 and the bypass middle area MDDA, from among the data transmission lines DTTRL, a seventh data transmission line DTTRL7 for transmitting the data signal of the seventh data line DL7 of the bypass middle area MDDA may be directly electrically connected to the seventh data line DL7.

According to one or more embodiments, the first read-out bypass line RODTL1, the first data bypass line DTDTL1, and the second data bypass line DTDTL2 may be limitedly (e.g., selectively) disposed in a part of the bypass area DEA.

Accordingly, because the end of each of the first read-out bypass line RODTL1, the first data bypass line DTDTL1, and the second data bypass line DTDTL2 may be arranged with a regularity (e.g., a predetermined regularity), the visibility of the first read-out bypass line RODTL1, the first data bypass line DTDTL1, and the second data bypass line DTDTL2 may be increased.

To prevent or reduce such visibility, the first dummy lines DML1 may further include first auxiliary lines ASL1 disposed in a part of the display area DA where the first read-out bypass line RODTL1, the first data bypass line DTDTL1, and the second data bypass line DTDTL2 are not disposed.

For example, some of the first auxiliary lines ASL1 may extend to the non-display area NDA from both ends (e.g., opposite ends) of each of the first read-out bypass line RODTL1, the first data bypass line DTDTL1, and the second data bypass line DTDTL2.

In addition, some others of the first auxiliary lines ASL1 may be arranged in the general area GA.

Similarly, the first read-out connection line ROCNL1, the first data connection line DTCNL1, and the second data connection line DTCNL2 may be limitedly (e.g., selectively) disposed in a part of the bypass area DEA.

Accordingly, because the end of each of the first read-out connection line ROCNL1, the first data connection line DTCNL1, and the second data connection line DTCNL2 may be arranged with a regularity (e.g., a predetermined regularity), the visibility of the first read-out connection line ROCNL1, the first data connection line DTCNL1, and the second data connection line DTCNL2 may be increased.

In order to prevent or reduce such visibility, the second dummy lines DML2 may further include second auxiliary lines ASL2 disposed in a part of the display area DA where the first read-out connection line ROCNL1, the first data connection line DTCNL1, and the second data connection line DTCNL2 are not disposed.

For example, some of the second auxiliary lines ASL2 may be paired with the first data line DL1 and the seventh data line DL7 from among the data lines DL that are not paired with the first read-out connection line ROCNL1, the first data connection line DTCNL1, and the second data connection line DTCNL2.

In addition, some others of the second auxiliary lines ASL2 may extend to the non-display area NDA from the end of each of the first read-out connection line ROCNL1, the first data connection line DTCNL1, and the second data connection line DTCNL2.

The second power ELVSS may be applied to the first auxiliary lines ASL1 and the second auxiliary lines ASL2.

According to one or more embodiments, the circuit layer 120 may further include a first power supply line VDSPL and a second power supply line VSSPL that transmit the first power ELVDD and the second power ELVSS, respectively, for driving the light emitting elements LE.

The first power supply line VDSPL and the second power supply line VSSPL may be disposed in the non-display area NDA, and may extend to the sub-region SBA.

The first power supply line VDSPL may be electrically connected to a first power pad for transmitting the first power ELVDD from among the signal pads SPD disposed in the second sub-region SB2.

The second power supply line VSSPL may be electrically connected to a second power pad for transmitting the second power ELVSS from among the signal pads SPD disposed in the second sub-region SB2.

The first auxiliary lines ASL1 may be electrically connected to the second power supply line VSSPL.

The second auxiliary lines ASL2 may be electrically connected to the first auxiliary lines ASL1 and the second power supply line VSSPL.

According to one or more embodiments, the circuit layer 120 may further include a second power auxiliary line VSAL disposed in the same layer as that of the data lines DL and the second dummy lines DML2, and electrically connected to the second power supply line VSSPL.

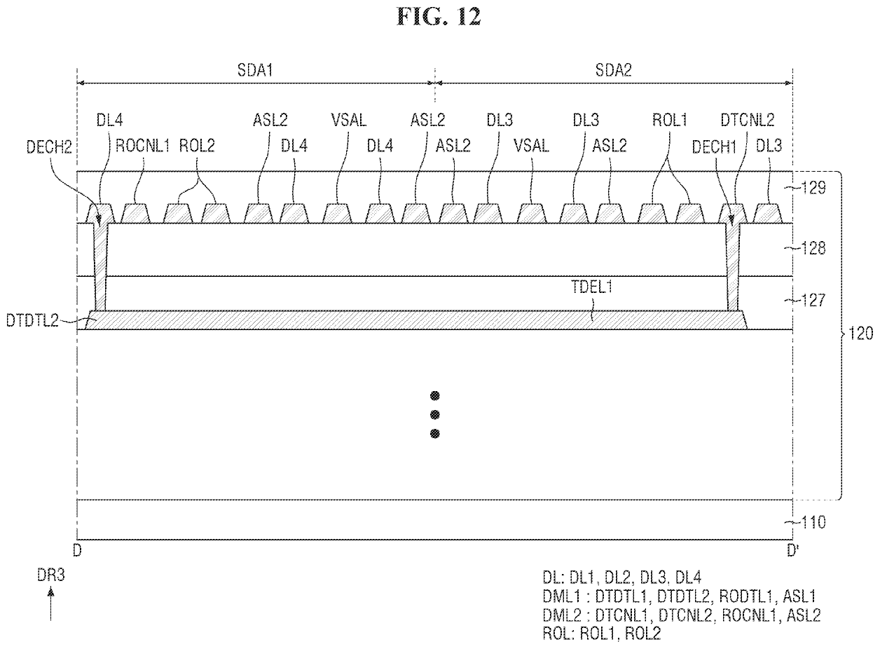

FIG. 12 is a cross-sectional view taken along the line D-D′ of FIG. 11.

Referring to FIG. 12, the data lines DL, the read-out lines ROL, and the second dummy lines DML2 may be disposed on at least one insulating layer 127, 128 that covers the first dummy lines DML1.

In other words, the data lines DL including the first to fourth data lines DL1 to DL4 and the seventh data line DL7, the read-out lines ROL including the first and second read-out lines ROL1 and ROL2, the second dummy lines DML2 including the first read-out connection line ROCNL1, the first data connection line DTCNL1, the second data connection line DTCNL2, and the second auxiliary lines ASL2 may be disposed in the third source/drain conductive layer on the second planarization layer 128.

The first dummy lines DML1 including the first read-out bypass line RODTL1, the first data bypass line DTDTL1, the second data bypass line DTDTL2, and the first auxiliary lines ASL1 may be disposed in a conductive layer below (e.g., under) the second planarization layer 128.

For example, the first dummy lines DML1 including the first read-out bypass line RODTL1, the first data bypass line DTDTL1, the second data bypass line DTDTL2, and the first auxiliary lines ASL1 may be disposed in the first source/drain conductive layer on the second interlayer insulating layer 126, and may be covered with the first planarization layer 127.

The second data bypass line DTDTL2 may be electrically connected to the second data connection line DTCNL2 through a first bypass connection hole DECH1. The second data bypass line DTDTL2 may be electrically connected to the fourth data line DL4 through a second bypass connection hole DECH2.

The first bypass connection hole DECH1 and the second bypass connection hole DECH2 may penetrate the second planarization layer 128 and the first planarization layer 127.

As shown in FIG. 11, according to an embodiment C_1, at least one first read-out bypass line RODTL1 may be arranged between the first data bypass lines DTDTL1 in the second direction DR2, or between the second data bypass lines DTDTL2 in the second direction DR2.

In other words, the first read-out bypass line RODTL1 may be adjacent to the first data bypass line DTDTL1 or the second data bypass line DTDTL2.

As a result, the signal of the first read-out bypass line RODTL1 may be easily distorted.

In other words, the signal of the first read-out bypass line RODTL1 may be distorted due to a coupling interference with the data signal of the first data bypass line DTDTL1 or the data signal of the second data bypass line DTDTL2.

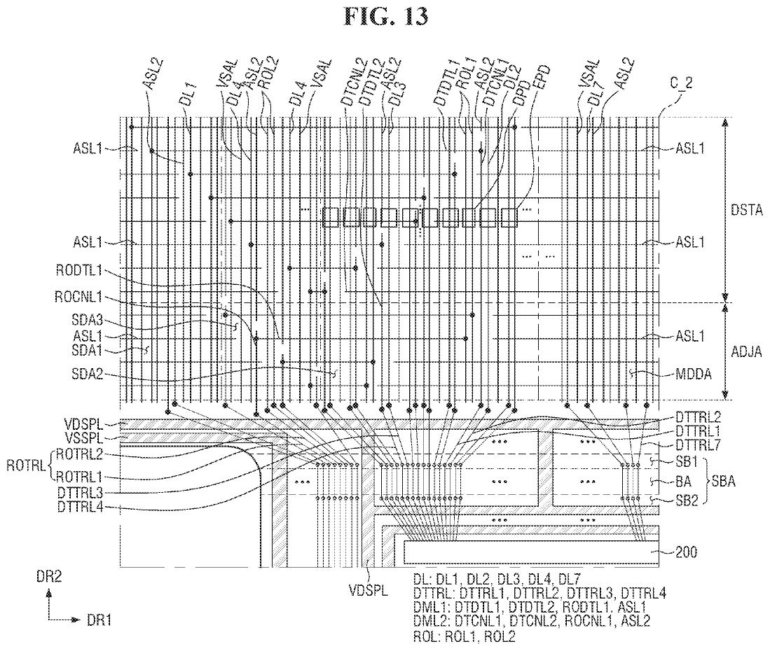

The embodiments described in more detail hereinafter with reference to FIGS. 13 through 15 may help to prevent or reduce the distortion of the first read-out bypass line RODTL1.

FIGS. 13 through 15 are enlarged layout diagrams illustrating the part C of FIG. 10 according to one or more embodiments.

Referring to FIG. 13, the display device 100 according to an embodiment C_2 may be the same or substantially the same as that of the embodiment C_1 described above with reference to FIGS. 11 and 12, except that each of the first bypass side area SDA1, the second bypass side area SDA2, and the third bypass side area SDA3 includes an adjacent region ADJA in contact with the non-display area NDA in the second direction DR2, and a separation region DSTA that is a remaining region excluding the adjacent region ADJA. The first read-out bypass line RODTL1 may be disposed in the adjacent region ADJA of each of the first bypass side area SDA1, the second bypass side area SDA2, and the third bypass side area SDA3. The first data bypass line DTDTL1 and the second data bypass line DTDTL2 are disposed in the separation region DSTA of each of the first bypass side area SDA1, the second bypass side area SDA2, and the third bypass side area SDA3. Accordingly, redundant description may not be repeated, and the differences may be described in more detail hereinafter.

In each of the first bypass side area SDA1, the second bypass side area SDA2, and the third bypass side area SDA3, the separation region DSTA may be disposed between the adjacent region ADJA and the general area GA.

As such, the first read-out bypass line RODTL1 may be disposed in the adjacent region ADJA of each of the first bypass side area SDA1, the second bypass side area SDA2, and the third bypass side area SDA3. The first data bypass line DTDTL1 and the second data bypass line DTDTL2 may be disposed in the separation region DSTA of each of the first bypass side area SDA1, the second bypass side area SDA2, and the third bypass side area SDA3. Thus, the first read-out bypass line RODTL1 may not be adjacent to the first data bypass line DTDTL1 or the second data bypass line DTDTL2.

In other words, because the first read-out bypass line RODTL1 may be spaced apart from the first data bypass line DTDTL1 and the second data bypass line DTDTL2, an effect of the data signal of the first data bypass line DTDTL1 or the data signal of the second data bypass line DTDTL2 on the signal of the first read-out bypass line RODTL1 may be reduced. Accordingly, distortion of the signal of the first read-out bypass line RODTL1 may be reduced.

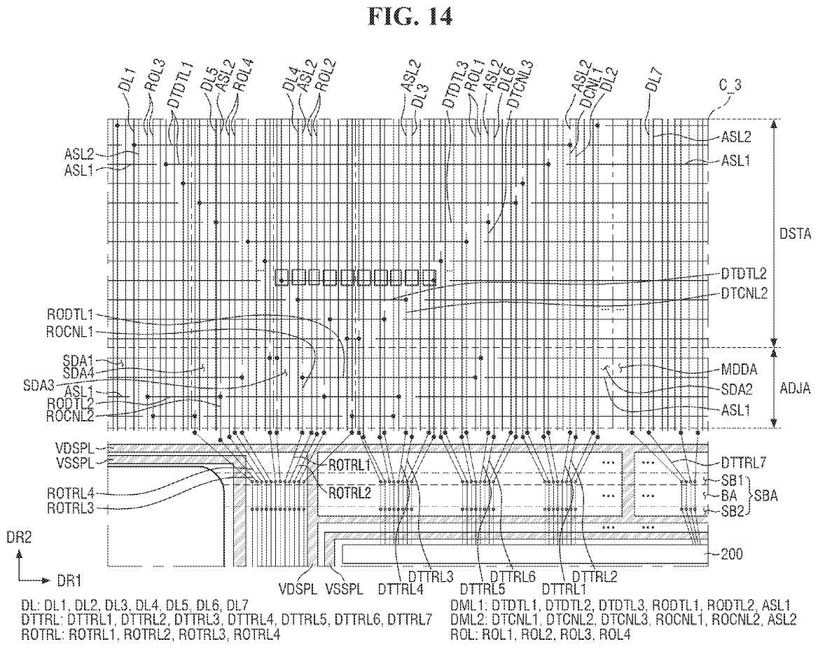

Referring to FIG. 14, the display device 100 according to an embodiment C_3 may be the same or substantially the same as that of the embodiment C_2 described above with reference to FIG. 13, except that the bypass area DEA of the display area DA may further include a fourth bypass side area SDA4 disposed between the first bypass side area SDA1 and the third bypass side area SDA3. Accordingly, redundant description may not be repeated, and the differences may be described in more detail hereinafter.

According to the embodiment C_3 illustrated in FIG. 14, the data lines DL may further include a fifth data line DL5 disposed in the fourth bypass side area SDA4.

The read-out lines ROL may further include a third read-out line ROL3 disposed in the first bypass side area SDA1, and a fourth read-out line ROL4 disposed in the fourth bypass side area SDA4.

The first dummy lines DML1 may further include a second read-out bypass line RODTL2 electrically connected to the third read-out line ROL3.

The second dummy lines DML2 may further include a second read-out connection line ROCNL2 that is paired with the fifth data line DL5 of the fourth bypass side area SDA4, and electrically connected to the second read-out bypass line RODTL2.

From among the read-out transmission lines ROTRL, a third read-out transmission line ROTRL3 for transmitting the signal of the third read-out line ROL3 may be electrically connected to the third read-out line ROL3 of the first bypass side area SDA1 through the second read-out connection line ROCNL2 of the fourth bypass side area SDA4 and the second read-out bypass line RODTL2.

From among the read-out transmission lines ROTRL, a fourth read-out transmission line ROTRL4 for transmitting the signal of the fourth read-out line ROL4 may be electrically connected to the fourth read-out line ROL4 of the fourth bypass side area SDA4.

According to the embodiment C_3 illustrated in FIG. 14, the data lines DL may further include a sixth data line DL6 disposed in the second bypass side area SDA2.

The first dummy lines DML1 may further include a third data bypass line DTDTL3 electrically connected to the fifth data line DL5.

The second dummy lines DML2 may further include a third data connection line DTCNL3 that is paired with the sixth data line DL6, and electrically connected to the third data bypass line DTDTL3.

From among the data transmission lines DTTRL, a fifth data transmission line DTTRL5 for transmitting the data signal of the fifth data line DL5 may be electrically connected to the fifth data line DL5 of the fourth bypass side area SDA4 through the third data connection line DTCNL3 of the second bypass side area SDA2 and the third data bypass line DTDTL3.

From among the data transmission lines DTTRL, a sixth data transmission line DTTRL6 for transmitting the data signal of the sixth data line DL6 may be directly electrically connected to the sixth data line DL6 of the second bypass side area SDA2.

According to the embodiment C_3 illustrated in FIG. 14, the first read-out bypass line RODTL1 that connects the first read-out line ROL1 of the second bypass side area SDA2 to the first read-out connection line ROCNL1 of the third bypass side area SDA3 may be disposed in the adjacent region ADJA of each of the second bypass side area SDA2 and the third bypass side area SDA3.

The second read-out bypass line RODTL2 that connects the third read-out line ROL3 of the first bypass side area SDA1 to the second read-out connection line ROCNL2 of the fourth bypass side area SDA4 may be disposed in the adjacent region ADJA of each of the first bypass side area SDA1 and the fourth bypass side area SDA4.

The first data bypass line DTDTL1 and the second data bypass line DTDTL2 may be disposed in the separation region DSTA of each of the first bypass side area SDA1, the second bypass side area SDA2, the third bypass side area SDA3, and the fourth bypass side area SDA4.

Further, the third data bypass line DTDTL3 may also be disposed in the separation region DSTA of each of the first bypass side area SDA1, the second bypass side area SDA2, the third bypass side area SDA3, and the fourth bypass side area SDA4.

As such, according to the embodiment C_3 illustrated in FIG. 14, the read-out transmission lines ROTRL may be clustered in a part of the non-display area NDA adjacent to the third bypass side area SDA3 and the fourth bypass side area SDA4.

In other words, the read-out transmission lines ROTRL may not extend into the first bypass side area SDA1 adjacent to the bent corner of the substrate 110, as well as into the second bypass side area SDA2 and the bypass middle area MDDA where the data transmission lines DTTRL extend, and thus, the width of a part of the non-display area NDA adjacent to the bent corner of the substrate 110 may be further reduced.

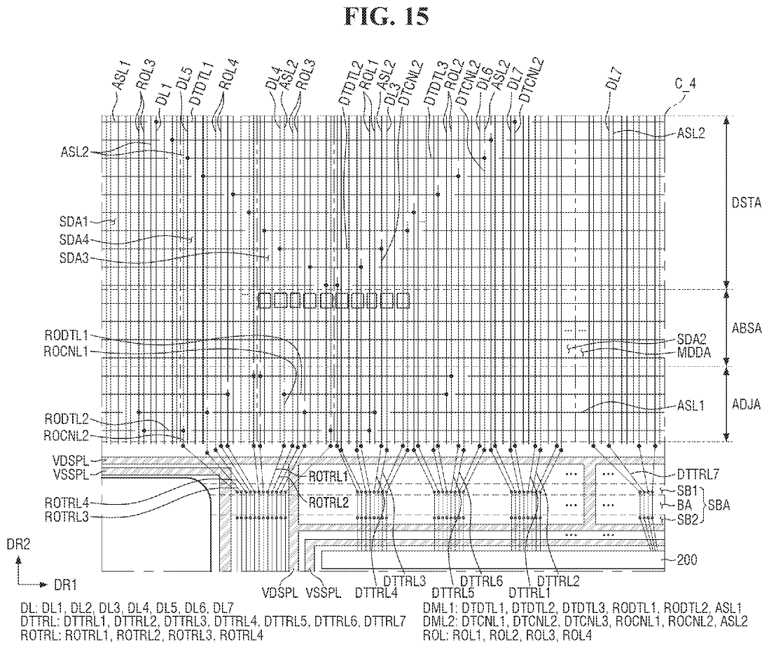

Referring to FIG. 15, the display device 100 according to an embodiment C_4 may be the same or substantially the same as that of the embodiment C_3 described above with reference to FIG. 14, except that each of the first bypass side area SDA1, the second bypass side area SDA2, the third bypass side area SDA3, and the fourth bypass side area SDA4 may further include a buffer region ABSA disposed between the adjacent region ADJA and the separation region DSTA. Accordingly, redundant description may not be repeated, and the differences may be described in more detail hereinafter.

According to the embodiment C_4 illustrated in FIG. 15, the first auxiliary lines ASL1 to which the second power ELVSS is applied may be disposed in the buffer region ABSA of each of the first bypass side area SDA1, the second bypass side area SDA2, the third bypass side area SDA3, and the fourth bypass side area SDA4.

As such, due to the arrangement of the buffer region ABSA, the first read-out bypass line RODTL1 and the second read-out bypass line RODTL2 may be further spaced apart from the first data bypass line DTDTL1, the second data bypass line DTDTL2, and the third data bypass line DTDTL3. Therefore, an effect of the data signal of the first data bypass line DTDTL1, the data signal of the second data bypass line DTDTL2, and the data signal of the third data bypass line DTDTL3 on the signal of the first read-out bypass line RODTL1 and the signal of the second read-out bypass line RODTL2 may be reduced.

In addition, the signal of the first read-out bypass line RODTL1 and the signal of the second read-out bypass line RODTL2 may be more stably maintained by the second power ELVSS of the first auxiliary lines ASL1.

Accordingly, a signal distortion of the first read-out bypass line RODTL1 and a signal distortion of the second read-out bypass line RODTL2 may be greatly reduced.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising:
a display area comprising emission areas, a non-emission area as a separation region between the emission areas, and light sensing areas in parts of the non-emission area; and
a non-display area around the display area;
a circuit layer on the substrate; and
an element layer on the circuit layer, and comprising:
light emitting elements in the emission areas, respectively; and
light sensing elements in the light sensing areas, respectively, wherein the circuit layer comprises:
light emitting pixel drivers electrically connected to the light emitting elements, respectively;
light sensing pixel drivers electrically connected to the light sensing elements, respectively;
data lines electrically connected to the light emitting pixel drivers;
read-out lines electrically connected to the light sensing pixel drivers, and extending parallel to the data lines;
first dummy lines extending in a first direction crossing the data lines, and comprising a first read-out bypass line electrically connected to a first read-out line from among the read-out lines; and
second dummy lines extending in a second direction parallel to the data lines and crossing the first direction, and paired with the data lines, respectively, the second dummy lines comprising a first read-out connection line electrically connected to the first read-out bypass line.

2. The display device of claim 1, wherein the data lines, the read-out lines, and the second dummy lines are located on at least one insulating layer covering the first dummy lines.

3. The display device of claim 2, further comprising a scanning driving circuit configured to collect light sensing signals from the light sensing elements through the light sensing pixel drivers and the read-out lines,
wherein the circuit layer further comprises read-out transmission lines in the non-display area, and electrically connected between the read-out lines and the scanning driving circuit, and
wherein from among the read-out transmission lines, a first read-out transmission line configured to transmit a signal of the first read-out line is electrically connected to the first read-out line through the first read-out connection line and the first read-out bypass line.

4. The display device of claim 3, wherein a bypass area on one side of the display area comprises:
a central bypass middle area;
a first bypass side area parallel to the bypass middle area in the first direction, and in contact with the non-display area;
a second bypass side area between the bypass middle area and the first bypass side area; and
a third bypass side area between the first bypass side area and the second bypass side area,
wherein the data lines comprise:
a first data line in the first bypass side area;
a second data line and a third data line in the second bypass side area; and
a fourth data line in the third bypass side area,
wherein the first dummy lines further comprise a first data bypass line electrically connected to the first data line, and a second data bypass line electrically connected to the fourth data line,
wherein the second dummy lines further comprise:
a first data connection line paired with the second data line, and electrically connected to the first data bypass line; and
a second data connection line paired with the third data line, and electrically connected to the second data bypass line, and
wherein the first read-out connection line is paired with the fourth data line.

5. The display device of claim 4, further comprising a display driving circuit configured to transmit data signals for the light emitting pixel drivers to the data lines,
wherein the circuit layer further comprises data transmission lines in the non-display area, and electrically connected between the data lines and the display driving circuit, and
wherein from among the data transmission lines:
a first data transmission line configured to transmit a data signal of the first data line is electrically connected to the first data line through the first data bypass line and the first data connection line;
a second data transmission line configured to transmit a data signal of the second data line is directly electrically connected to the second data line;
a third data transmission line configured to transmit a data signal of the third data line is directly electrically connected to the third data line; and
a fourth data transmission line configured to transmit a data signal of the fourth data line is electrically connected to the first data line through the second data bypass line and the second data connection line.

6. The display device of claim 5, wherein the substrate comprises a main region comprising the display area and the non-display area, and a sub-region protruding from one side of the main region in the second direction,
wherein the display driving circuit is on the sub-region of the substrate,
wherein the scanning driving circuit is on a display circuit board connected to the sub-region of the substrate,
wherein the data transmission lines are clustered in a part of the non-display area parallel to the second bypass side area, and
wherein the read-out transmission lines are clustered in another part of the non-display area adjacent to the third bypass side area.

7. The display device of claim 6, wherein the first read-out line is located in the second bypass side area,
wherein the read-out lines further comprise a second read-out line in the third bypass side area, and
wherein from among the read-out transmission lines, a second read-out transmission line configured to transmit a signal of the second read-out line is directly electrically connected to the second read-out line.

8. The display device of claim 7, wherein the first read-out bypass line comprises a plurality of first read-out bypass lines,
wherein the first data bypass line comprises a plurality of first data bypass lines,
wherein the second data bypass line comprises a plurality of second data bypass lines, and
wherein at least one of the first read-out bypass lines is located between the first data bypass lines in the second direction, or between the second data bypass lines in the second direction.

9. The display device of claim 7, wherein each of the first bypass side area, the second bypass side area, and the third bypass side area comprises:
an adjacent region in contact with the non-display area in the second direction; and
a separation region as a remaining region excluding the adjacent region,
wherein the first read-out bypass line is located in the adjacent region of each of the first bypass side area, the second bypass side area, and the third bypass side area, and
wherein the first data bypass line and the second data bypass line are located in the separation region of each of the first bypass side area, the second bypass side area, and the third bypass side area.

10. The display device of claim 7, wherein the bypass area of the display area further comprises a fourth bypass side area between the first bypass side area and the third bypass side area,
wherein the data lines further comprise a fifth data line in the fourth bypass side area,
wherein the read-out lines further comprise a third read-out line in the first bypass side area, and a fourth read-out line in the fourth bypass side area,
wherein the first dummy lines further comprise a second read-out bypass line electrically connected to the third read-out line,
wherein the second dummy lines further comprise a second read-out connection line paired with the fifth data line, and electrically connected to the second read-out bypass line, and
wherein from among the read-out transmission lines:
a third read-out transmission line configured to transmit a signal of the third read-out line is electrically connected to the third read-out line through the second read-out connection line and the second read-out bypass line; and
a fourth read-out transmission line configured to transmit a signal of the fourth read-out line is directly electrically connected to the fourth read-out line.

11. The display device of claim 10, wherein the data lines further comprise a sixth data line in the second bypass side area,
wherein the first dummy lines further comprise a third data bypass line electrically connected to the fifth data line, and
wherein the second dummy lines further comprise a third data connection line paired with the sixth data line, and electrically connected to the third data bypass line.

12. The display device of claim 10, wherein the fourth bypass side area comprises an adjacent region in contact with the non-display area in the second direction, and a separation region as a remaining region excluding the adjacent region,
wherein the first read-out bypass line is located in the adjacent region of each of the second bypass side area and the third bypass side area,
wherein the second read-out bypass line is located in the adjacent region of each of the first bypass side area and the fourth bypass side area, and
wherein the first data bypass line and the second data bypass line are located in the separation region of each of the first bypass side area, the second bypass side area, the third bypass side area, and the fourth bypass side area.

13. The display device of claim 12, wherein the circuit layer further comprises a first power supply line and a second power supply line in the non-display area, and configured to transmit a first power and a second power, respectively, for driving the light emitting elements,
wherein the first dummy lines further comprise first auxiliary lines electrically connected to the second power supply line, and
wherein the second dummy lines further comprise second auxiliary lines electrically connected to the first auxiliary lines and the second power supply line.

14. The display device of claim 13, wherein each of the first bypass side area, the second bypass side area, the third bypass side area, and the fourth bypass side area further comprises a buffer region between the adjacent region and the separation region, and
wherein the first auxiliary lines are located in the buffer region of each of the first bypass side area, the second bypass side area, the third bypass side area, and the fourth bypass side area.

15. The display device of claim 7, wherein the circuit layer further comprises:
a first power supply line and a second power supply line in the non-display area, and configured to transmit a first power and a second power, respectively, for driving the light emitting elements; and
a first power line electrically connected between the light emitting pixel drivers and the first power supply line,
wherein one of the light emitting elements is electrically connected between one of the light emitting pixel drivers and the second power,
wherein one of the light sensing elements is electrically connected between an element output node of one of the light sensing pixel drivers and the second power,
wherein the one of the light emitting pixel drivers comprises:
a first transistor configured to generate a driving current for driving the one of the light emitting elements;
a second transistor electrically connected between one of the data lines and a first electrode of the first transistor;
a third transistor electrically connected between a gate electrode of the first transistor and a second electrode of the first transistor;
a fourth transistor electrically connected between a first initialization power line configured to transmit a first initialization power and the gate electrode of the first transistor;
a fifth transistor electrically connected between the first power line and the first electrode of the first transistor;
a sixth transistor electrically connected between the second electrode of the first transistor and the one of the light emitting elements;
a seventh transistor electrically connected between a second initialization power line configured to transmit a second initialization power and the one of the light emitting elements; and
an eighth transistor electrically connected between a bias power line configured to transmit a bias power and the first electrode of the first transistor, and
wherein the one of the light sensing pixel drivers comprises:
a ninth transistor configured to be turned on according to a voltage level of the element output node;
a tenth transistor electrically connected between a reset voltage line configured to transmit a reset voltage and the element output node; and
an eleventh transistor electrically connected between one of the read-out lines and the ninth transistor.

16. A display device comprising:
a substrate comprising:
a display area comprising emission areas, a non-emission area as a separation region between the emission areas, and light sensing areas in parts of the non-emission area; and
a non-display area around the display area;
a circuit layer on the substrate; and
an element layer on the circuit layer, and comprising:
light emitting elements in the emission areas, respectively; and
light sensing elements in the light sensing areas, respectively, wherein a bypass area on one side of the display area comprises:
a central bypass middle area;
a first bypass side area parallel to the bypass middle area in a first direction, and in contact with the non-display area;
a second bypass side area between the bypass middle area and the first bypass side area; and
a third bypass side area between the first bypass side area and the second bypass side area, and
wherein the circuit layer comprises:
light emitting pixel drivers electrically connected to the light emitting elements, respectively;
light sensing pixel drivers electrically connected to the light sensing elements;
data lines electrically connected to the light emitting pixel drivers;
read-out lines electrically connected to the light sensing pixel drivers, and extending parallel to the data lines;
a first data bypass line extending in the first direction crossing the data lines, and electrically connected to a first data line in the first bypass side area from among the data lines;
a first read-out bypass line extending in the first direction crossing the data lines, and electrically connected to a first read-out line from among the read-out lines;
a first data connection line extending in a second direction parallel to the data lines and crossing the first direction, the first data connection line paired with a second data line in the second bypass side area from among the data lines, and electrically connected to the first data bypass line; and
a first read-out connection line extending in the second direction, and electrically connected to the first read-out bypass line.

17. The display device of claim 16, wherein the data lines further comprise a third data line in the second bypass side area, and a fourth data line in the third bypass side area,
wherein the first read-out connection line is paired with the fourth data line, and
wherein the circuit layer further comprises:
a second data bypass line extending in the first direction, and electrically connected to the fourth data line; and
a second data connection line extending in the second direction, paired with the third data line, and electrically connected to the second data bypass line.

18. The display device of claim 17, further comprising:
a scanning driving circuit configured to collect light sensing signals from the light sensing elements through the light sensing pixel drivers and the read-out lines; and
a display driving circuit configured to transmit data signals for the light emitting pixel drivers to the data lines,
wherein the circuit layer further comprises:
read-out transmission lines in the non-display area, and electrically connected between the read-out lines and the scanning driving circuit; and
data transmission lines in the non-display area, and electrically connected between the data lines and the display driving circuit, wherein from among the data transmission lines:
a first data transmission line configured to transmit a data signal of the first data line is electrically connected to the first data line through the first data bypass line and the first data connection line,
a second data transmission line configured to transmit a data signal of the second data line is directly electrically connected to the second data line,
a third data transmission line configured to transmit a data signal of the third data line is directly electrically connected to the third data line, and
a fourth data transmission line configured to transmit a data signal of the fourth data line is electrically connected to the first data line through the second data bypass line and the second data connection line, and
wherein from among the read-out transmission lines, a first read-out transmission line configured to transmit a signal of the first read-out line is electrically connected to the first read-out line through the first read-out connection line and the first read-out bypass line.

19. The display device of claim 18, wherein the read-out lines further comprise a second read-out line in the third bypass side area, and
wherein from among the read-out transmission lines, a second read-out transmission line configured to transmit a signal of the second read-out line is directly electrically connected to the second read-out line.

20. The display device of claim 19, wherein the first read-out bypass line comprises a plurality of first read-out bypass lines,
wherein the first data bypass line comprises a plurality of first data bypass lines,
wherein the second data bypass line comprises a plurality of second data bypass lines, and
wherein at least one of the first read-out bypass lines is located between the first data bypass lines in the second direction, or between the second data bypass lines in the second direction.

21. The display device of claim 19, wherein each of the first bypass side area, the second bypass side area, and the third bypass side area comprises:
an adjacent region in contact with the non-display area in the second direction; and
a separation region as a remaining region excluding the adjacent region,
wherein the first read-out bypass line is located in the adjacent region of each of the first bypass side area, the second bypass side area, and the third bypass side area, and
wherein the first data bypass line and the second data bypass line are located in the separation region of each of the first bypass side area, the second bypass side area, and the third bypass side area.

22. The display device of claim 21, wherein the bypass area of the display area further comprises a fourth bypass side area between the first bypass side area and the third bypass side area,
wherein the data lines further comprise a fifth data line in the fourth bypass side area, and a sixth data line in the second bypass side area,
wherein the read-out lines further comprise a third read-out line in the first bypass side area, and a fourth read-out line in the fourth bypass side area,
wherein the circuit layer further comprises:
a second read-out bypass line extending in the first direction, and electrically connected to the third read-out line;
a second read-out connection line extending in the second direction, paired with the fifth data line, and electrically connected to the second read-out bypass line;
a third data bypass line extending in the first direction, and electrically connected to the fifth data line; and
a third data connection line extending in the second direction, paired with the sixth data line, and electrically connected to the third data bypass line, and wherein from among the read-out transmission lines:
a third read-out transmission line configured to transmit a signal of the third read-out line is electrically connected to the third read-out line through the second read-out connection line and the second read-out bypass line; and
a fourth read-out transmission line configured to transmit a signal of the fourth read-out line is directly electrically connected to the fourth read-out line.

23. The display device of claim 22, wherein the fourth bypass side area comprises an adjacent region in contact with the non-display area in the second direction, and a separation region as a remaining region excluding the adjacent region,
wherein the first read-out bypass line is located in the adjacent region of each of the second bypass side area and the third bypass side area,
wherein the second read-out bypass line is located in the adjacent region of each of the first bypass side area and the fourth bypass side area, and
wherein the first data bypass line and the second data bypass line are located in the separation region of each of the first bypass side area, the second bypass side area, the third bypass side area, and the fourth bypass side area.

24. The display device of claim 23, wherein the circuit layer further comprises:
a first power supply line and a second power supply line in the non-display area, and configured to transmit a first power and a second power, respectively, for driving the light emitting elements; and
first auxiliary lines extending in the first direction, and electrically connected to the second power supply line,
wherein each of the first bypass side area, the second bypass side area, the third bypass side area, and the fourth bypass side area further comprises a buffer region between the adjacent region and the separation region, and
wherein the first auxiliary lines are located in the buffer region of each of the first bypass side area, the second bypass side area, the third bypass side area, and the fourth bypass side area.
